(19) United States
(12) Patent Application Publication
(10) Pub. No.: US 2025/0095693 A1
(43) Pub. Date: Mar. 20, 2025

(54) CONNECTIONS OF BIT LINES AND WORD LINES IN STACKED MEMORY LAYERS TO A COMPLEMENTARY METAL-OXIDE-SEMICONDUCTOR LAYER

(71) Applicant: Intel Corporation, Santa Clara, CA (US)

(72) Inventors: Abhishek A. Sharma, Portland, OR (US); Juan G. Alzate-Vinasco, Tigard, OR (US); Fatih Hamzaoglu, Portland, OR (US); Wilfred Gomes, Portland, OR (US); Anand S. Murthy, Portland, OR (US); Tahir Ghani, Portland, OR (US); Van H. Le, Beaverton, OR (US)

(73) Assignee: Intel Corporation, Santa Clara, CA (US)

(21) Appl. No.: 18/467,947

(22) Filed: Sep. 15, 2023

(51) Int. Cl. G11C 5/06; G11C 11/4091; G11C 11/419

(52) U.S. Cl. CPC G11C 5/063; G11C 11/4091; G11C 11/419

(57) ABSTRACT

An IC device may include a CMOS layer and memory layers at the frontside and backside of the CMOS layer. The CMOS layer may include one or more logic circuits, which may include MOSFET transistors. A memory layer may include one or more memory arrays. A memory array may include memory cells (e.g., DRAM cells), bit lines, and word lines. The logic circuits may include word line drivers and sense amplifiers. Word lines in different memory layers may share the same word line driver. Bit lines in different memory layers may share the same sense amplifier. The IC device may include front-back word line drivers, near-far sense amplifiers, near-far word line drivers, or front-back sense amplifiers. A memory layer may be bonded with the CMOS layer through a bonding layer that provides a bonding interface between the memory layer and the CMOS layer.

### BACKGROUND

Integrated circuit (IC) fabrication usually includes two stages. The first stage is referred to as the front end of line (FEOL). The second stage is referred to as the back end of line (BEOL). In the FEOL, individual semiconductor devices components (e.g., transistor, capacitors, resistors, etc.) can be patterned on a wafer. The FEOL stage may include a complementary metal-oxide-semiconductor (CMOS) process, in which metal-oxide-semiconductor field-effect transistors (MOSFETs) (such as symmetrical pairs of P-type and N-type MOSFETs) can be fabricated. In the BEOL, metal layers, vias, and insulating layers can be formed to get the individual components interconnected. The BEOL usually starts with forming the first metal layer on the wafer. The first metal layer is often called M0. More metal layers can be formed on top of MO, and these metal layers are often called M1, M2, and so on.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a perspective view of an IC device with memory layers at both frontside and backside of a CMOS layer, according to some embodiments of the disclosure.

FIG. 2 is an IC device with memory layers sharing word line drivers in a CMOS layer, according to some embodiments of the disclosure.

FIG. 3 illustrates an IC device with memory layers sharing sense amplifiers in a CMOS layer, according to some embodiments of the disclosure.

FIG. 4 illustrates an IC device with memory layers sharing word line drivers and sense amplifiers in a CMOS layer, according to some embodiments of the present disclosure.

FIGS. 5A and 5B illustrate an IC device with memory layers sharing word line drivers and sense amplifiers in a CMOS layer that is boned to the memory layers through bonding layers, according to some embodiments of the present disclosure.

FIGS. 6A and 6B illustrate another IC device with memory layers sharing word line drivers and sense amplifiers in a CMOS layer that is boned to the memory layers through bonding layers, according to some embodiments of the present disclosure.

FIG. 7 illustrates an IC device including a stack of wafers, according to some embodiments of the disclosure.

FIG. 8 is an electric circuit diagram of an example dynamic random-access memory (DRAM) array, according to some embodiments of the present disclosure.

FIG. 9A is an electric circuit diagram of an example static random-access memory (SRAM) cell, according to some embodiments of the present disclosure.

FIG. 9B provides a top-down plan view of an example implementation of the SRAM cell, according to some embodiments of the present disclosure.

FIGS. 10A and 10B are top views of a wafer and dies that can facilitate stacked memory layers with bit lines and word lines connected to a CMOS layer, according to some embodiments of the disclosure.

FIG. 11 is a side, cross-sectional view of an example IC package that may include stacked memory layers with bit lines and word lines connected to a CMOS layer, according to some embodiments of the disclosure.

FIG. 12 is a cross-sectional side view of an IC device assembly that may include components having stacked memory layers with bit lines and word lines connected to a CMOS layer, according to some embodiments of the disclosure.

FIG. 13 is a block diagram of an example computing device that may include one or more components with stacked memory layers with bit lines and word lines connected to a CMOS layer, according to some embodiments of the disclosure.

### DETAILED DESCRIPTION

The systems, methods, and devices of this disclosure each have several innovative aspects, no single one of which is solely responsible for all the desirable attributes disclosed herein. Details of one or more implementations of the subject matter described in this specification are set forth in the description below and the accompanying drawings.

Embodiments of the present disclosure are applicable to different types of memory devices. Some embodiments of the present disclosure may refer to SRAM. Other embodiments of the present disclosure may refer to DRAM. However, embodiments of the present disclosure may be equally applicable to memory cells implemented other technologies. Thus, in general, memory cells/arrays described herein may be implemented as standalone SRAM devices, DRAM devices, or any other volatile or nonvolatile memory cells/arrays.

A memory cell is a fundamental building block of computer memory devices used to store and retrieve data. It is a small unit of storage that can hold a single bit of information, which can be either a 0 or a 1. Memory cells are organized in a grid-like structure to form memory arrays. A memory cell usually includes a memory element, which stores information, and an access transistor, which is coupled to the memory element and controls access to the memory element. A memory device also includes bit lines and word lines coupled to memory cells. A bit line can couple the memory cells in the memory array to the memory control circuitry. A bit line can be used for reading and writing data. A word line can be used to control the access to a specific row of memory cells in the memory array. When the word line is activated, it enables the data stored in the selected row to be read or modified.

Currently available memory devices usually have logic circuits in memory layers. A memory layer may be a memory die or memory wafer. Such logic circuits may be peripheral circuits, such as sense amplifiers, decoders timers, and so on. Fabrication of such memory layers can require CMOS processes. However, CMOS processes are not always cost efficient. The cost of manufacturing such memory layers can be higher than desired.

Embodiments of the present disclosure may improve on at least some of the challenges and issues described above by providing memory layers arranged at frontside and backside of CMOS layers. In an example, a CMOS layer may include logic circuits or devices that are fabricated using one or more CMOS processes. Memory layers may be fabricated using non-CMOS processes, such as BEOL process. The memory layers may be placed at the frontside and the backside of the CMOS layer. The memory layers may be bonded to the CMOS layer. Also, the memory layer may be electrically coupled to the CMOS layer so that logic circuits or devices in the CMOS layer may control operations of the memory layers. The logic functions in the CMOS layer can facilitate computation in memory. The cost of fabricating the memory layers can be reduced as usage of CMOS fabrication is avoided.

In various embodiments of the present disclosure, an IC device, which may also be referred to as “IC assembly,” includes a CMOS layer is at least partially fabricated using a CMOS process. The CMOS layer may include transistors (e.g., MOSFETs) fabricated using the CMOS process. The transistors may be used to form logic circuits. Additionally or alternatively, the transistor may be used in memory cells, e.g., SRAM cells. Memory layers may be attached to the frontside and backside of the CMOS layer. For instance, one or more memory layers may be arranged at each of the frontside and backside. A memory layer may include one or more memory arrays. A memory array may include memory cells coupled to bit lines and word lines. A memory cell in a memory layer may be a DRAM cell, SRMA cell, magnetoresistive random-access memory (MRAM) cell, ferroelectric memory cell, and so on. The CMOS layer may include logic circuits or devices that control access to memory cells in the memory layers. A memory layer may be bonded with the CMOS layer through a bonding layer. The bonding layer may provide a hybrid bonding interface (HBI). In an example, the bonding layer may include a bonding material that facilitates adhesion between the memory layer and the CMOS layer. The bonding layer may also include conductive structures that couple one or more logic circuits in the CMOS layer to one or more memory arrays in the memory layer.

Word lines and bit lines in the memory layers are coupled to logic circuits or devices in the CMOS layer. For instance, the CMOS layer may include one or more word line drivers, sense amplifiers, row decoders, column decoders, and so on. Word lines in the memory layers are coupled to the word line drivers. Bit lines in the memory layers are coupled to the sense amplifiers. Word lines in different memory layers may share a word line driver. Similarly, bit lines in different memory layers may share a sense amplifier. In an example, a group of word lines, each of which is in a different memory layer, may be coupled to the same word line driver, but bit lines in these memory layers may be coupled to different sense amplifiers. In another example, a group of bit lines, each of which is in a different memory layer, may be coupled to the same sense amplifier, but word lines in these memory layers may be coupled to different word line drivers. In yet another example, the connections of word lines and bit lines to the CMOS layer may be based on a configuration including front-back word line drivers and near-far sense amplifiers or a configuration including front-back sense amplifiers and near-far word line drivers.

It should be noted that, in some settings, the term “nanoribbon” has been used to describe an elongated semiconductor structure that has a substantially rectangular transverse cross-section (e.g., a cross-section in a plane perpendicular to the longitudinal axis of the structure), while the term “nanowire” has been used to describe a similar structure but with a substantially circular or square transverse cross-sections. In the following, a single term “nanoribbon” is used to describe an elongated semiconductor structure independent of the shape of the transverse cross-section. Thus, as used herein, the term “nanoribbon” is used to cover elongated semiconductor structures that have substantially rectangular transverse cross-sections (possibly with rounded corners), elongated semiconductor structures that have substantially square transverse cross-sections (possibly with rounded corners), elongated semiconductor structures that have substantially circular or elliptical/oval transverse cross-sections, as well as elongated semiconductor structures that have any polygonal transverse cross-sections. A longitudinal axis of a structure refers to a line (e.g., an imaginary line) that runs down the center of the structure in a direction perpendicular to a transverse cross-section of the structure.

In the following, some descriptions may refer to a particular source or drain (S/D) region or contact being either a source region/contact or a drain region/contact. However, unless specified otherwise, which region/contact of a transistor or diode is considered to be a source region/contact and which region/contact is considered to be a drain region/contact is not important because, as is common in the field of field-effect transistors (FETs), designations of source and drain are often interchangeable. Therefore, descriptions of some illustrative embodiments of the source and drain regions/contacts provided herein are applicable to embodiments where the designation of source and drain regions/contacts may be reversed.

As used herein, the term “metal layer” may refer to a layer above a substrate that includes electrically conductive interconnect structures for providing electrical connectivity between different IC components. Metal layers described herein may also be referred to as “interconnect layers” to clearly indicate that these layers include electrically conductive interconnect structures which may, but do not have to be, metal.

The systems, methods and devices of this disclosure each have several innovative aspects, no single one of which is solely responsible for all of the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art. For example, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. If used, the terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−20% of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value based on the context of a particular value as described herein or as known in the art.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the term “or” refers to an inclusive “or” and not to an exclusive “or.” The phrase “A and/or B” or the phase “A or B” means (A), (B), or (A and B). For the purposes of the present disclosure, the phrase “A, B, and/or C” or the phase “A, B, or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

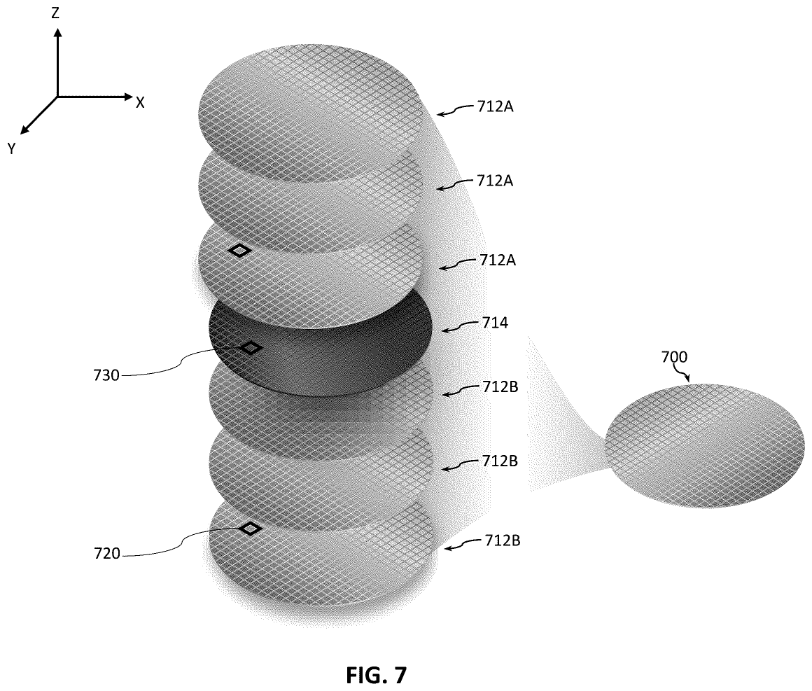

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense. For convenience, if a collection of drawings designated with different letters are present, e.g., FIGS. 7A-7B, such a collection may be referred to herein without the letters, e.g., as “FIG. 7.”

In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using e.g., Physical Failure Analysis (PFA) would allow determination of presence of stacked memory layers with bit lines and word lines connected to a CMOS layer as described herein.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Various stacked memory layers with bit lines and word lines connected to a CMOS layer as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

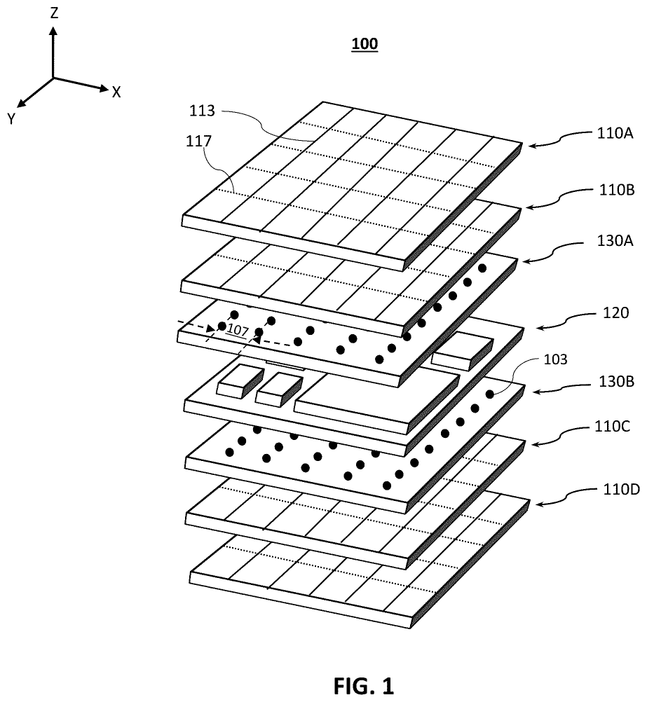

FIG. 1 is a perspective view of an IC device 100 with memory layers 110A-110D (collectively referred to as “memory layers 110” or “memory layer 110”) at both frontside and backside of a CMOS layer 120, according to some embodiments of the disclosure. The IC device 100 also includes bonding layers 130A and 130B. In other embodiments, the IC device 100 may include fewer, more, or different components. The IC device 100 may also be referred to as an IC device or IC assembly.

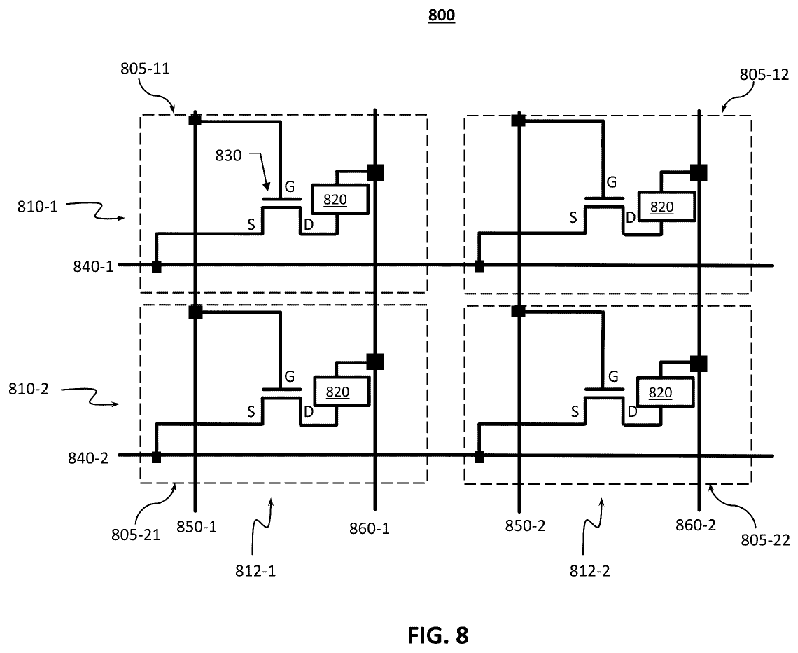

Each memory layer 110 may be a memory die or memory wafer. In some embodiments, each memory layer 110 includes one or more memory arrays. A memory array may include memory cells, word lines 113 (individually referred to as “word line”), bit lines 117 (individually referred to as “bit line 117”). For the purpose of simplicity and illustration, memory cells are not shown in FIG. 1. In some embodiments, memory arrays in the memory layers 110 are DRAM arrays. More details regarding DRAM array and DRAM cell are provided below in conjunction with FIG. 8.

An example memory cell may include a memory element and one or more access transistors. An example memory element includes a capacitor. A memory cell may be coupled to a word line 113 and a bit line 117. A memory cell may be activated or accessed (e.g., for data read or write operations) using the corresponding word line and bit line. In some embodiments, the memory cells in the memory array 115 are arranged in rows and columns. A row of memory cells may be coupled to a word line 113. The word line 113 may be used to access the memory cells in the row. Each word line 113 may be coupled to a word line driver. The word line 113 may also be coupled to a row decoder that can select which word lines 113 to activate based on an output from the word line driver. When the word line 113 is activated, the row of memory cells may be selected and accessed for data read operations or data write operations. The word lines 113 may also be referred to as row select lines.

A column of memory cells may be connected to a bit line 117. The bit line 117 may be used to access the memory cells in the column. In some embodiments, each column of memory cells is connected to two bit lines 117: a first bit line 117 and a second bit line 117 that is the inverse of the first bit line 117. A bit of data may be stored in a column of memory cells. Each bit line may be coupled to a column decoder that can select which bit lines 117 to activate. When the bit line 117 is activated, the column of memory cells may be selected and accessed for data read operations or data write operations. A bit line 117 may also be coupled to a sense amplifier. In some embodiments, the sense amplifier may be arranged between the column decoder and the bit line 117.

A transistor in a memory cell may receive power or signal from the CMOS layer 120. For instance, an electrode over the source or drain region of the transistor may be coupled to a power via and the power via may be coupled to a power interconnect in the CMOS layer 120. Additionally or alternatively, the transistor may receive a signal from the CMOS layer 120. For instance, a gate electrode in the transistor may be coupled to a signal via, and the signal via may be coupled to a signal interconnect in the CMOS layer 120. In some embodiments, each memory layer 110 may be a DRAM device that includes DRAM arrays.

As shown in FIG. 1, the memory layers 110A and 110B are at the frontside of the CMOS layer 120, and the memory layers 110C and 110D are at the backside of the CMOS layer 120. In other embodiments, the IC device 100 may include a different number of memory layers 110 at the frontside or backside of the CMOS layer 120. The memory layers 110 may be fabricated through a different process from the CMOS layer 120. For instance, the CMOS layer 120 may be fabricated using one or more CMOS processes, in which MOSFETs may be formed. The CMOS process(es) may be part of a FEOL process. The MOSFETs may be used in logic circuits in the CMOS layer 120 for controlling operations of the memory cells in memory layer 110. In contrast, transistors of memory cells in the memory layers 110 may be fabricated through a BEOL process, which does not require CMOS fabrication. Transistors of memory cells in the memory layers 110 may be referred to as backend transistors.

In some embodiments, the memory layers 110 may be fabricated separately from each other or from the CMOS layer 120. A memory layer 110 may be coupled to the CMOS layer 120 after the CMOS layer 120 is formed. In an example, the memory layer 110B or memory layer 110C may be attached to the CMOS layer 120 (e.g., using the bonding layer 130A or 130B) after the CMOS layer 120 is formed. After the attachment, the memory layer 110A may be placed over the memory layer 110B, and the memory layer 110D may be placed over the memory layer 110C. In another example, the memory layers 110A and 110B may be assembled into one memory layer set and after that, the memory layer set is attached to the frontside of the CMOS layer 120. Similarly, the memory layers 110C and 110D may be assembled into one memory layer set and after that, the memory layer set is attached to the backside of the CMOS layer 120. One or more additional memory layers 110 may be added to the frontside or backside of the CMOS layer 120. Given the presence of the CMOS layer 120 between the memory layers 110, the IC device 100 is capable of “computation in memory.” The process for fabricating the memory layer 110 can cost less than the CMOS process and therefore, the overall cost for fabricating the IC device 100 can be reduced.

Each memory layer 110 may include one or more semiconductor structures, which may facilitate formation of transistors in the memory layer 110. A semiconductor structure may provide semiconductor regions (e.g., channel region, source region, drain region, etc.) of backend transistors in the memory layer 110. For the purpose of simplicity and illustration, other components (e.g., gate, source electrode, drain electrode, etc.) of backend transistors are not shown in FIG. 1. In some embodiments, a semiconductor structure may include a channel material. The channel material may be composed of semiconductor material systems including, for example, N-type or P-type materials systems. In some embodiments, the channel material 104 may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the channel material 104 may include a combination of semiconductor materials where one semiconductor material may be used for a channel portion of a transistor and another material, sometimes referred to as a “blocking material,” may be used between the channel portion and the support structure over which the transistor is provided. In some embodiments, the channel material may include a monocrystalline semiconductor, such as silicon (Si) or germanium (Ge). In some embodiments, the channel material may include a compound semiconductor with a first sub-lattice of at least one element from group III of the periodic table (e.g., Al, Ga, In), and a second sub-lattice of at least one element of group V of the periodic table (e.g., P, As, Sb).

For some example N-type transistor embodiments (i.e., for the embodiments where the transistors implemented in the memory layers 110 are N-type metal-oxide-semiconductor (NMOS) transistors), the channel portions of the channel material may advantageously include a III-V material having a high electron mobility, such as, but not limited to InGaAs, InP, InSb, and InAs. For some such embodiments, the channel portions of the channel material may be a ternary III-V alloy, such as InGaAs, GaAsSb, InAsP, or InPSb. For some InₓGa₁₋ₓAs fin embodiments, In content (x) may be between 0.6 and 0.9, and may advantageously be at least 0.7 (e.g., In_{0.7}Ga_{0.3}As). In some embodiments with highest mobility, the channel portions of the channel material may be an intrinsic III-V material, i.e., a III-V semiconductor material not intentionally doped with any electrically active impurity. In alternate embodiments, a nominal impurity dopant level may be present within the channel portions of the channel material, for example to further fine-tune a threshold voltage Vt, or to provide HALO pocket implants, etc. Even for impurity-doped embodiments however, impurity dopant level within the channel portions of the channel material may be relatively low, for example below 10¹⁵ dopant atoms per cubic centimeter (cm⁻³), and advantageously below 10¹³ cm⁻³.

For some example P-type transistor embodiments (i.e., for the embodiments where the transistors implemented in the memory layers 110 are P-type metal-oxide-semiconductor (PMOS) transistors), the channel portions of the channel material may advantageously be a group IV material having a high hole mobility, such as, but not limited to Ge or a Ge-rich SiGe alloy. For some example embodiments, the channel portions of the channel material may have a Ge content between 0.6 and 0.9, and advantageously may be at least 0.7. In some embodiments with highest mobility, the channel portions of the channel material may be intrinsic III-V (or IV for P-type devices) material and not intentionally doped with any electrically active impurity. In alternate embodiments, one or more a nominal impurity dopant level may be present within the channel material, for example to further set a threshold voltage (Vt), or to provide HALO pocket implants, etc. Even for impurity-doped embodiments however, impurity dopant level within the channel portions of the channel material is relatively low, for example below 10¹⁵ cm⁻³, and advantageously below 10¹³ cm⁻³.

In some embodiments, the transistors implemented in the memory layers 110 may be thin film transistors (TFTs). A TFT is a special kind of a field-effect transistor made by depositing a thin film of an active semiconductor material, as well as a dielectric layer and metallic contacts, over a supporting layer that may be a non-conducting layer. At least a portion of the active semiconductor material forms a channel of the TFT. If transistors implemented in the memory layers 110 are TFTs, the channel material may include a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, for TFTs, the channel material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphite, and black phosphorus, each of which may possibly be doped with one or more of gallium, indium, aluminum, fluorine, boron, phosphorus, arsenic, nitrogen, tantalum, tungsten, and magnesium, etc. In some embodiments, the channel material may have a thickness between about 5 and 75 nanometers, including all values and ranges therein. In some embodiments, a thin film channel material may be deposited at relatively low temperatures, which allows depositing the channel material within the thermal budgets imposed on backend fabrication to avoid damaging other components, e.g., frontend components such as the logic devices of the CMOS layer 120.

The CMOS layer 120 may be a logic layer, such as a logic die or logic wafer, which may also be referred to as a compute die/wafer or compute logic die/wafer. The CMOS layer 120 controls the memory layers 110. The CMOS layer 120 may include one or more logic circuits that control operations of the memory layers 110. A logic circuit may be a peripheral circuit. A logic circuit may include transistors fabricated through a CMOS process. For instance, the transistors can be used to form word line drivers, row decoders, sense amplifiers, column decoders, timers, multipliers, CMOS logic, SRAM cells, power delivery network, signal delivery network, or other types of devices or circuits in the CMOS layer 120. In some embodiments, the architecture of transistors in the CMOS layer 120 may be different from that of transistors in the memory layers 110. In an example, the transistors in the CMOS layer 120 may have nanoribbon or nanowire semiconductor structures, while transistors in the memory layers 110 may have fin semiconductor structures.

A row decoder may select which rows of memory cells in memory arrays to be accessed based on memory addresses. In some embodiments, the row decoder may receive an input signal with information indicating a memory address. The row decoder may decode the memory address and select the row(s) corresponding to the memory address. The row decoder may further activate the row(s), e.g., by selecting and enabling the word line 113 of each selected row. After a row is selected and activated, the logic circuit can perform read or write operations on the memory cells in the row. The row decoder may include a digital circuit that can be used to decode memory addresses, select rows of memory cells, or activate word lines. The digital circuit may include one or more logic gates.

A word line driver drives signals down word lines 113. In some embodiments, the word line driver may receive signals from another component of the CMOS layer 120 (e.g., a row decoder) or from a circuit outside the IC device 100. The word line driver may amplify the signals and apply the amplified signals to word lines, e.g., word lines selected by a row decoder. The word line driver can generate the necessary voltage levels to activate word lines. In some embodiments, the word line driver may be coupled to one or more row decoders and one or more word lines 113. The word line driver may be implemented between a row decoder and a word line 113. In other embodiments, the word line driver may be included in a row decoder. In some embodiments, the word line driver may include one or more inverters to drive word lines 113.

A column decoder selects which column(s) of memory cells in memory arrays to be accessed based on memory addresses received from a logic circuit. The column decoder may decode a column address and activate the corresponding column of memory cells. The column decoder may include a digital circuit that can take the column address as input and generate one or more control signals that activate the corresponding column of memory cells. The digital circuit may include a combination of logic gates, such as AND gates and inverters, to decode the address and generate the necessary control signals. The number of inputs and outputs of the column decoder may depend on the size of the memory array. For example, in a memory system with 8 columns, the memory column decoder would have 3 address inputs (since 2\hat{ }3=8) and 8 output signals, each corresponding to a specific column. When a particular column address is provided, the column decoder may activate the corresponding output signal, enabling the memory cells in that column for read or write operations. The row decoder and column decoder can facilitate efficient and accurate access to specific rows of memory cells within the memory array and can support retrieval and storage of data in computer systems.

A sense amplifier may amplify and restore weak signals, e.g., to a more robust and usable level. In some embodiments, for reading data from the memory layers 110, the sense amplifier may detect and amplify the small voltage difference between the stored data states, typically representing binary values of 0 and 1. By amplifying this voltage difference, the sense amplifier can enable accurate and reliable data retrieval. In some embodiments (e.g., embodiments having high speed data transmission), the sense amplifier may amplify weak signals to avoid signal degradation and noise during signal propagation so that the signals can be more immune to noise, which can enable more accurate data recovery. The sense amplifier may be a latch-based sense amplifier, differential sense amplifier, dynamic sense amplifier, or other types of sense amplifiers. In some embodiments, the sense amplifier may be coupled to one or more column decoders and one or more bit lines 117. The sense amplifier may be implemented between a column decoder and a bit line 117. For instance, signals may be processed by the column decoder, then amplified by the sense amplifier before being provided to the bit line 117.

As described below, the memory layers 110 may be bonded with the CMOS layer 120 through the bonding layers 130A and 130B (collectively referred to as “bonding layers 130” or “bonding layer 130”). Each bonding layer 130 includes a plurality of conductive structures 103 for coupling components in the corresponding memory layer 110 to the CMOS layer 120. For instance, a conductive structure 103 may have an end connected to one or more components (e.g., via, interconnect, transistor, etc.) in the memory layer 110 and another end connected to one or more components (e.g., via, interconnect, transistor, etc.) in the CMOS layer 120. The conductive structures 103 may facilitate power delivery from the CMOS layer to the memory layers 110 and signal delivery between the CMOS layer and the memory layers 110. A conductive structure 103 may be, or may include, a via. The via may be a through silicon via (TSV) in some embodiments. The conductive structures 103 may have a pitch 107. The pitch 107 is a center-to-center distance of two adjacent conductive structures 103. In some embodiments, the pitch 107 is in a range from approximately 100 nm to approximately 15 micrometers. Even though the pitch 107 is a distance along the X axis in FIG. 1, the conductive structures 103 may have the same or similar pitch along the Y axis.

In some embodiments, the bonding layer 130A provides a HBI between the memory layer 110B and the CMOS layer 120, and the bonding layer 130B provides a HBI between the memory layer 110C and the CMOS layer 120. In some embodiments, hybrid bonding may be performed either on a wafer-level, e.g., wafers may be hybrid bonded before they are separated into dies. In other embodiments, hybrid bonding may be performed on a die-level, e.g., dies may be hybrid bonded after the corresponding wafers have been separated into dies.

In general, hybrid manufacturing is described herein with reference to a first IC structure (e.g., a memory layer 110) and a second IC structure (e.g., the CMOS layer 120) bonded to one another using a bonding material. The first and second IC structures may be fabricated by different manufacturers, using different materials, or different manufacturing techniques. For each IC structure, the terms “bottom face” or “backside” of the structure may refer to the back of the IC structure, e.g., bottom of the support structure of a given IC structure, while the terms “top face” or “frontside” of the structure may refer to the opposing other face. When the top face of the first IC structure is bonded to the top face of the second IC structure, the structures are described as bonded “face-to-face” (f2f). When the top face of the first IC structure is bonded to the bottom face of the second IC structure or the bottom face of the first IC structure is bonded to the top face of the second IC structure, the structures are described as bonded “face-to-back” (f2b). When the bottom face of the first IC structure is bonded to the bottom face of the second IC structure, the structures are described as bonded “back-to-back” (b2b).

In some embodiments, bonding of the faces of the first and second IC structures may be performing using insulator-insulator bonding, e.g., as oxide-oxide bonding, where an insulating material of the first IC structure is bonded to an insulating material of the second IC structure. In some embodiments, a bonding material may be present in between the faces of the first and second IC structures that are bonded together. The bonding material may be applied to the one or both faces of the first and second IC structures that should be bonded and then the first and second IC structures are put together, possibly while applying a suitable pressure and heating up the assembly to a suitable temperature (e.g., to moderately high temperatures, e.g., between about 50 and 200 degrees Celsius) for a duration of time. In some embodiments, the bonding material may be an adhesive material that ensures attachment of the first and second IC structures to one another. In some embodiments, the bonding material may be an etch-stop material. In some embodiments, the bonding material may be both an etch-stop material and have suitable adhesive properties to ensure attachment of the first and second IC structures to one another. In some embodiments, the bonding material may include silicon, nitrogen, and carbon, where the atomic percentage of any of these materials may be at least 1%, e.g., between about 1% and 50%, indicating that these elements are added deliberately, as opposed to being accidental impurities which are typically in concentration below about 0.1%. Having both nitrogen and carbon in these concentrations in addition to silicon is not typically used in conventional semiconductor manufacturing processes where, typically, either nitrogen or carbon is used in combination with silicon, and, therefore, could be a characteristic feature of the hybrid bonding. Using an etch-stop material at the interface (i.e., the interface between the first and second IC structures) that includes include silicon, nitrogen, and carbon, where the atomic percentage of any of these materials may be at least 1%, e.g., SiOCN, may be advantageous in terms that such a material may act both as an etch-stop material, and have sufficient adhesive properties to bond the first and second IC structures together. In addition, an etch-stop material at the interface between the first and second IC structures that includes include silicon, nitrogen, and carbon, where the atomic percentage of any of these materials may be at least 1%, may be advantageous in terms of improving etch-selectivity of this material with respect to etch-stop materials that may be used in different of the first and second IC structures.

In some embodiments, no bonding material may be used, but there will still be a bonding interface resulting from the bonding of the first and second IC structures to one another. Such a bonding interface may be recognizable as a seam or a thin layer in the microelectronic assembly, using, e.g., selective area diffraction (SED), even when the specific materials of the insulators of the first and second IC structures that are bonded together may be the same, in which case the bonding interface would still be noticeable as a seam or a thin layer in what otherwise appears as a bulk insulator (e.g., bulk oxide) layer.

In some embodiments, one or more of conductive structures (e.g., power via, signal via, etc.) may be provided after the memory layers 110 and the CMOS layer 120 have been hybrid bonded. A via may extend from one surface of a CMOS layer 120 towards the opposing surface of the CMOS layer 120, and may extend through the corresponding bonding layer 130, to provide signal and/or power to various IC components (e.g., transistors) in the memory layer 110. A conductive structure may further extend through the memory layer 110 and into the next one or more memory layers 110 to facilitate signal or power delivery for the next memory layer(s) 110.

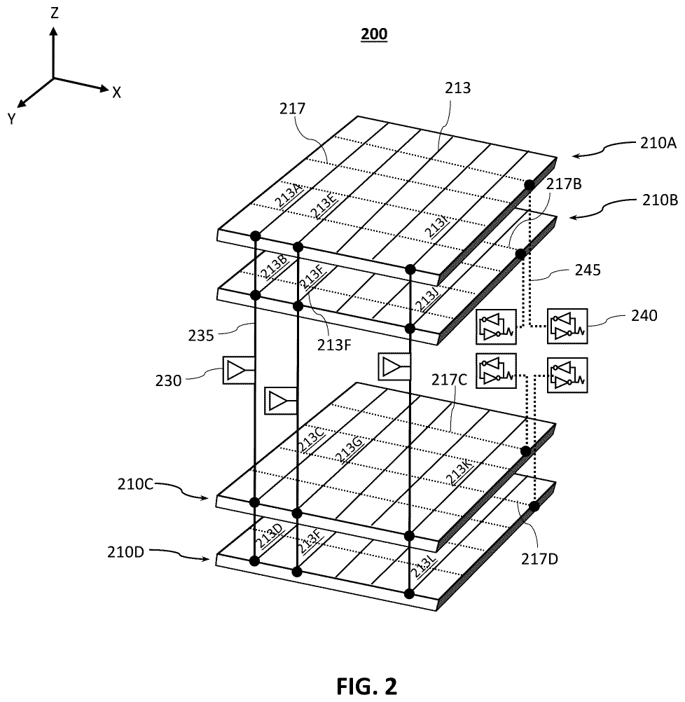

FIG. 2 is an IC device 200 with memory layers 210A-210D sharing word line drivers 230 in a CMOS layer, according to some embodiments of the disclosure. The IC device 200 may be an example of the IC device 100 of FIG. 1. In the embodiments of FIG. 2, the CMOS layer is between the memory layers 210B and 210C, so that the memory layers 210A and 210B are at the frontside of the CMOS layer versus the memory layers 210C and 210D are at the backside of the CMOS layer. The four memory layers 210A-210D may be referred to as “memory layers 210” or “memory layer 210.” In other embodiments, the IC device 200 may include a different number of memory layers at either side of the CMOS layer. For the purpose of illustration, the CMOS layer is not shown in FIG. 2. Also, the IC device 200 may include other components that are not shown in FIG. 2, such as bonding layers, vias, and so on.

The CMOS layer provides power and signals to the memory layers 210. The CMOS layer may also receive signals (e.g., data stored in the memory layers 210) from the memory layers 210. The CMOS layer may be an example of the CMOS layer 120 in FIG. 1. In the embodiments of FIG. 2, the CMOS layer includes four word line drivers 230 (individually referred to as “word line driver 230”) and three sense amplifiers 240 (individually referred to as “sense amplifier 240”). Even though not shown in FIG. 2, the CMOS layer may include other components, such as row decoders, column decoders, SRAM arrays, and so on. The word line drivers 230 may be separate from each other. In some embodiments, the word line drivers 230 are separated from each other by one or more electrical insulators. The sense amplifiers 240 may also be separate from each other. In some embodiments, the sense amplifiers 240 are separated from each other by one or more electrical insulators.

Each memory layer 210 includes word lines 213 (individually referred to as “word line 213”) and bit lines 217 (individually referred to as “word line 213”). Each memory layer 210 may also include memory cells coupled to the word lines 213 and bit lines 217. The word lines 213 may be examples of the word lines 113 in FIG. 1, the bit lines 217 may be examples of the bit lines 117 in FIG. 1. The memory layers 210 may be examples of the memory layers 110 in FIG. 1. In some embodiments, the word lines 213 are coupled to the word line drivers 230 in the CMOS layer, and the bit lines 217 are coupled to the sense amplifiers 240 in the CMOS layer.

For the purpose of simplicity and illustration, FIG. 2 shows connections between representative word lines 213A-213L and the word line drivers 230 and connections between representative bit lines 217A-217D and sense amplifiers 240. The IC device 200 may include other connections between word lines 213 and word line drivers 230 or other connections between bit lines 217 and sense amplifiers 240. As shown in FIG. 2, the word lines 213A, 213E, and 213I and bit line 217A are in the memory layer 210A; the word lines 213B, 213F, and 213J and bit line 217B are in the memory layer 210B; the word lines 213C, 213G, and 213K and bit line 217C are in the memory layer 210C; and the word lines 213D, 213H, and 213L and bit line 217D are in the memory layer 210D.

The word lines 213A-213D (i.e., a first word line group) share a first one of the word line drivers 230. The word lines 213E-213H (i.e., a second word line group) share a second one of the word line drivers 230. The word lines 213I-213L (i.e., a third word line group) share a third one of the word line drivers 230. Each of the four word line groups are coupled to the word line driver 230 through a conductive structure 235. The conductive structure 235 is connected to the four word lines 213 in the word line group and to the word line driver 230. The four word lines 213 in the same word line group may be activated by the same signal form the word line driver 230.

The four bit lines 217A-217D are coupled to the four sense amplifiers 240, respectively, through conductive structures 245 (individually referred to as “conductive structure 245”). Each conductive structure 245 is connected to one of the bitlines 217A-217D and a sense amplifier 240. conductive structure 235 or 245 may extend in a direction perpendicular to the memory layers 210. Each conductive structure 235 or 245 may include one or more vias, including TSVs. In some embodiments, the sense amplifiers 240 are multiplexed. The bit lines 217A-217D do not share sense amplifiers 240 with each other and can be activated separately. Even though word lines 213 in different memory layers 210 are coupled, the separation of bit lines 217 in different memory layers 210 can facilitate independent controls of memory cells in the memory layers 210. Memory cells in different memory layers 210 may have different memory addresses, based on which the memory cells may be located, selected, or accessed.

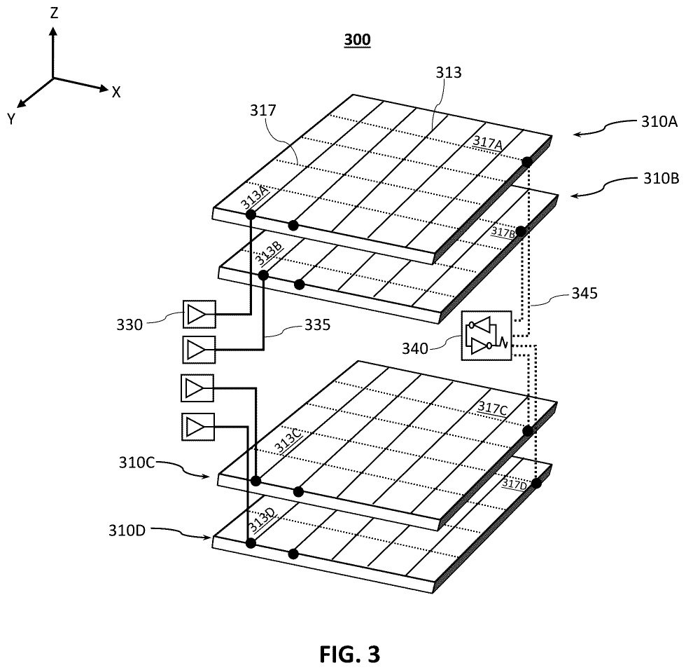

FIG. 3 illustrates an IC device with memory layers sharing sense amplifiers in a CMOS layer, according to some embodiments of the disclosure. The IC device 300 may be an example of the IC device 100 of FIG. 1. In the embodiments of FIG. 3, the CMOS layer is between the memory layers 310B and 310C, so that the memory layers 310A and 310B are at the frontside of the CMOS layer versus the memory layers 310C and 310D are at the backside of the CMOS layer. The four memory layers 310A-210D may be referred to as “memory layers 310” or “memory layer 310.” In other embodiments, the IC device 300 may include a different number of memory layers at either side of the CMOS layer. For the purpose of illustration, the CMOS layer is not shown in FIG. 3. Also, the IC device 300 may include other components that are not shown in FIG. 3, such as bonding layers, vias, and so on.

The CMOS layer provides power and signals to the memory layers 310. The CMOS layer may also receive signals (e.g., data stored in the memory layers 310) from the memory layers 310. The CMOS layer may be an example of the CMOS layer 120 in FIG. 1. In the embodiments of FIG. 3, the CMOS layer includes four word line drivers 330 (individually referred to as “word line driver 330”) and a sense amplifier 340. Even though not shown in FIG. 3, the CMOS layer may include other components, such as additional word line driver 330, additional sense amplifier 340, row decoders, column decoders, SRAM arrays, and so on. The word line drivers 330 may be separate from each other. In some embodiments, the word line drivers 330 are separated from each other by one or more electrical insulators.

Each memory layer 310 includes word lines 313 (individually referred to as “word line 313”) and bit lines 317 (individually referred to as “word line 313”). Each memory layer 310 may also include memory cells coupled to the word lines 313 and bit lines 317. The word lines 313 may be examples of the word lines 113 in FIG. 1, the bit lines 317 may be examples of the bit lines 117 in FIG. 1. The memory layers 310 may be examples of the memory layers 110 in FIG. 1. In some embodiments, the word lines 313 are coupled to the word line drivers 330 in the CMOS layer, and the bit lines 317 are coupled to the sense amplifiers 340 in the CMOS layer.

For the purpose of simplicity and illustration, FIG. 3 shows connections between representative word lines 313A-313D and the word line drivers 330 and connections between representative bit lines 317A-317D and sense amplifier 340. The IC device 300 may include other connections between word lines 313 and word line drivers 330 or other connections between bit lines 317 and sense amplifier 340. As shown in FIG. 3, the word line 313A and bit line 317A are in the memory layer 310A; the word line 313B and bit line 317B are in the memory layer 310B; the word line 313C and bit line 317C are in the memory layer 310C; and the word line 313D and bit line 317D are in the memory layer 310D.

The four word lines 313A-313D are coupled to the four word line drivers 330, respectively, through four conductive structures 335 (individually referred to as “conductive structure 335”). Each conductive structure 335 is connected to one of the word lines 313A-313D and one of the word line drivers 330. The word lines 313A-313D do not share word line drivers 330 with each other and can be activated separately. The bit lines 317A-317D share the sense amplifier 340. As shown in FIG. 3, the bit lines 317A-317D are all coupled to the sense amplifier 340 through conductive structures 345 (individually referred to as “conductive structure 345”). Each conductive structure 345 is connected to one of the bit lines 317A-317D and the sense amplifier 340. A conductive structure 335 or 345 may extend in a direction perpendicular to the memory layers 310. Each conductive structure 335 or 345 may include one or more vias, including TSVs. Even though bit lines 317 in different memory layers 310 are coupled, the separation of word lines 313 in different memory layers 310 can facilitate independent controls of memory cells in the memory layers 310. Memory cells in different memory layers 310 may have different memory addresses, based on which the memory cells may be located, selected, or accessed.

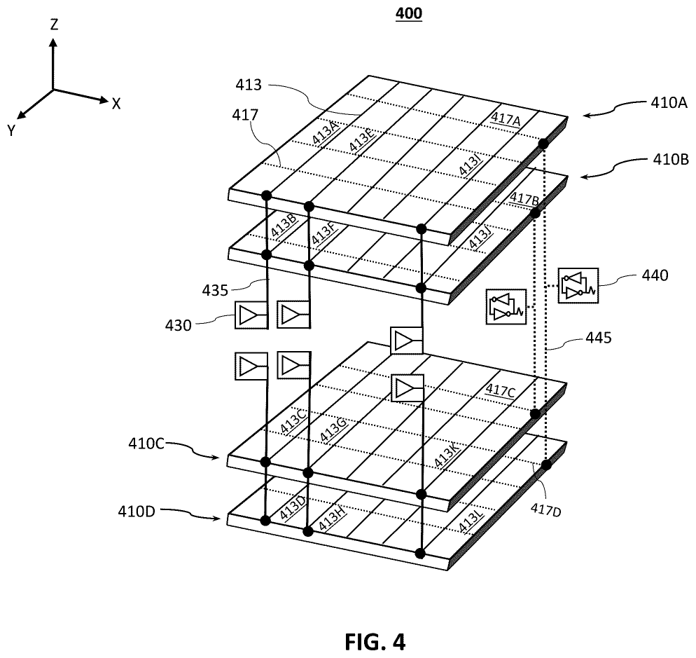

FIG. 4 illustrates an IC device with memory layers 410A-410D sharing word line drivers 430 and sense amplifiers 440 in a CMOS layer, according to some embodiments of the present disclosure. The IC device 400 may be an example of the IC device 100 of FIG. 1. In the embodiments of FIG. 4, the CMOS layer is between the memory layers 410B and 410C, so that the memory layers 410A and 410B are at the frontside of the CMOS layer versus the memory layers 410C and 410D are at the backside of the CMOS layer. The four memory layers 410A-410D may be referred to as “memory layers 410” or “memory layer 410.” In other embodiments, the IC device 400 may include a different number of memory layers at either side of the CMOS layer. For the purpose of illustration, the CMOS layer is not shown in FIG. 4. Also, the IC device 400 may include other components that are not shown in FIG. 4, such as bonding layers, vias, and so on.

The CMOS layer provides power and signals to the memory layers 410. The CMOS layer may also receive signals (e.g., data stored in the memory layers 410) from the memory layers 410. The CMOS layer may be an example of the CMOS layer 120 in FIG. 1. In the embodiments of FIG. 4, the CMOS layer includes word line drivers 430 (individually referred to as “word line driver 430”) and sense amplifiers 440 (individually referred to as “sense amplifier 440”). Even though not shown in FIG. 4, the CMOS layer may include other components, such as row decoders, column decoders, SRAM arrays, and so on. The word line drivers 430 may be separate from each other. In some embodiments, the word line drivers 430 are separated from each other by one or more electrical insulators. The sense amplifiers 440 may also be separate from each other. In some embodiments, the sense amplifiers 440 are separated from each other by one or more electrical insulators.

Each memory layer 410 includes word lines 413 (individually referred to as “word line 413”) and bit lines 417 (individually referred to as “word line 413”). Each memory layer 410 may also include memory cells coupled to the word lines 413 and bit lines 417. The word lines 413 may be examples of the word lines 113 in FIG. 1, the bit lines 417 may be examples of the bit lines 117 in FIG. 1. The memory layers 410 may be examples of the memory layers 110 in FIG. 1. In some embodiments, the word lines 413 are coupled to the word line drivers 430 in the CMOS layer, and the bit lines 417 are coupled to the sense amplifiers 440 in the CMOS layer.

For the purpose of simplicity and illustration, FIG. 4 shows connections between representative word lines 413A-413L and the word line drivers 430 and connections between representative bit lines 417A-417D and sense amplifiers 440. The IC device 400 may include other connections between word lines 413 and word line drivers 430 or other connections between bit lines 417 and sense amplifiers 440. As shown in FIG. 4, the word lines 413A, 413E, and 413I and bit line 417A are in the memory layer 410A; the word lines 413B, 413F, and 413J and bit line 417B are in the memory layer 410B; the word lines 413C, 413G, and 413K and bit line 417C are in the memory layer 410C; and the word lines 413D, 413H, and 413L and bit line 417D are in the memory layer 410D.

The word lines 413A-413L are in six word line groups: a first word line group including the word lines 413A and 413B, a second word line group including the word lines 413C and 413D, a third word line group including the word lines 413E and 413F, a fourth word line group including the word lines 413G and 413H, a fifth word line group including the word lines 413I and 413J, and a sixth word line group including the word lines 413K and 413L. Each word line group includes two word lines 413 that are in two memory layers 410, respectively, which are at the same side of the CMOS layer. The six word line group are coupled to the six word line drivers 430, respectively. The word line groups that includes word lines 413 in the memory layers 410A and 410B at the frontside of the CMOS layers are referred to as “frontside word line groups,” and the word line drivers 430 coupled to these word lines groups are referred to as “frontside word line driver.” The word line groups that include word lines 413 in the memory layers 410C and 410D at the backside of the CMOS layers are referred to as “backside word line groups,” and the word line drivers 430 coupled to these word lines groups are referred to as “backside word line driver.” Each word line group is coupled to a different word line driver 430 through a conductive structure 435. The conductive structure 435 is connected to the two word lines 413 in the word line group and to the corresponding word line driver 430. The word lines 413 in the same word line group may be activated by the same signal form the word line driver 430.

The bit lines 417A and 417D, which are in memory layers 410A and 410D that are father from the CMOS layer, are coupled to one of the sense amplifiers 440 through structures 445 (individually referred to as “conductive structure 445”). The sense amplifier 440 coupled to the bit lines 417A and 417D is referred to as a “far sense amplifier.” The bit lines 417B and 417C, which are in memory layers 417B and 417C that are closer to the CMOS layer, are coupled to the other one of the sense amplifiers 440 through additional structures 445. The sense amplifier 440 coupled to the bit lines 417B and 417D is referred to as a “near sense amplifier.” Each conductive structure 445 is connected to one of the bitlines 417A-417D and the corresponding sense amplifier 440. A conductive structure 435 or 445 may extend in a direction perpendicular to the memory layers 410. Each conductive structure 435 or 445 may include one or more vias, including TSVs.

With the “near-far” word line drivers and “front-back” sense amplifiers arrangement, memory cells in the memory layers 410 can still be separately accessed and activated, despite that the memory layers 410 share the word line drivers 430 and sense amplifiers 440. Memory cells in different memory layers 410 may have different memory addresses, based on which the memory cells may be located, selected, or accessed.

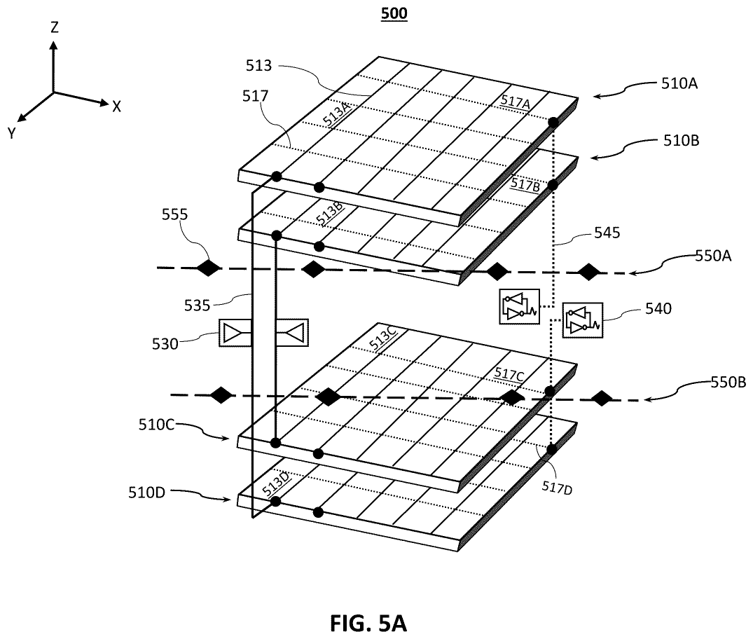

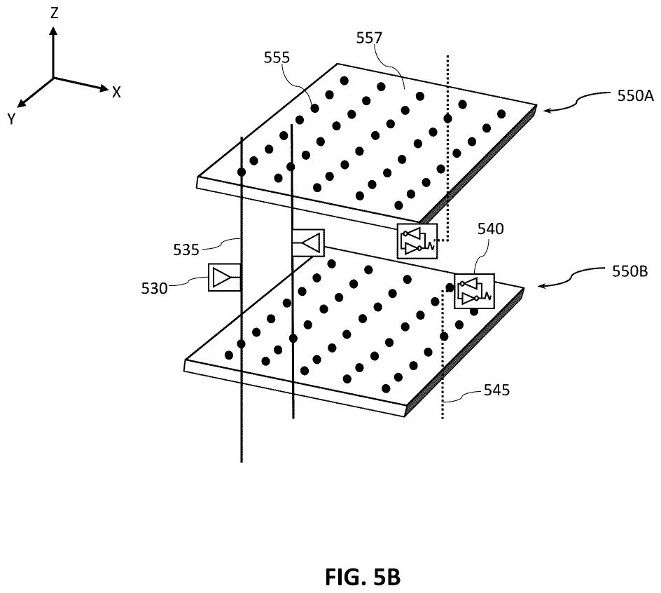

FIGS. 5A and 5B illustrates an IC device 500 with memory layers 510A-510D sharing word line drivers 530 and sense amplifiers 540 in a CMOS layer that is boned to the memory layers 510A-510D through bonding layers 550A and 550B, according to some embodiments of the present disclosure. The IC device 500 may be an example of the IC device 100 of FIG. 1. In the embodiments of FIGS. 5A and 5B, the CMOS layer is between the memory layers 510B and 510C, so that the memory layers 510A and 510B are at the frontside of the CMOS layer versus the memory layers 510C and 510D are at the backside of the CMOS layer. The four memory layers 510A-210D may be referred to as “memory layers 510” or “memory layer 510.” In other embodiments, the IC device 500 may include a different number of memory layers at either side of the CMOS layer. For the purpose of illustration, the CMOS layer is not shown in FIGS. 5A and 5B. Also, the IC device 500 may include other components that are not shown in FIGS. 5A and 5B, such as bonding layers, vias, and so on.

The CMOS layer provides power and signals to the memory layers 510. The CMOS layer may also receive signals (e.g., data stored in the memory layers 510) from the memory layers 510. The CMOS layer may be an example of the CMOS layer 120 in FIG. 1. In the embodiments of FIGS. 5A and 5B, the CMOS layer includes four word line drivers 530 (individually referred to as “word line driver 530”) and a sense amplifier 540. Even though not shown in FIGS. 5A and 5B, the CMOS layer may include other components, such as additional word line driver 530, additional sense amplifier 540, row decoders, column decoders, SRAM arrays, and so on. The word line drivers 530 may be separate from each other. In some embodiments, the word line drivers 530 are separated from each other by one or more electrical insulators.

Each memory layer 510 includes word lines 513 (individually referred to as “word line 513”) and bit lines 517 (individually referred to as “word line 513”). Each memory layer 510 may also include memory cells coupled to the word lines 513 and bit lines 517. The word lines 513 may be examples of the word lines 113 in FIG. 1, the bit lines 517 may be examples of the bit lines 117 in FIG. 1. The memory layers 510 may be examples of the memory layers 110 in FIG. 1. In some embodiments, the word lines 513 are coupled to the word line drivers 530 in the CMOS layer, and the bit lines 517 are coupled to the sense amplifiers 540 in the CMOS layer.

For the purpose of simplicity and illustration, FIGS. 5A and 5B show connections between representative word lines 513A-513D and the word line drivers 530 and connections between representative bit lines 517A-517D and sense amplifier 540. The IC device 500 may include other connections between word lines 513 and word line drivers 530 or other connections between bit lines 517 and sense amplifier 540. As shown in FIG. 5A, the word line 513A and bit line 517A are in the memory layer 510A; the word line 513B and bit line 517B are in the memory layer 510B; the word line 513C and bit line 517C are in the memory layer 510C; and the word line 513D and bit line 517D are in the memory layer 510D.

The IC device 500 has a “near-far” word line drivers plus “front-back” sense amplifiers arrangement. As shown in FIG. 5A, the word lines 513A and 513D (i.e., far word lines) are coupled to a word line driver 530 (i.e., a far word line driver). The word lines 513B and 513D (i.e., near word lines) are coupled to another word line driver 530 (i.e., a near word line driver). The word lines 513A-513D are coupled to the word line drivers 530 through conductive structures 535. The bit lines 517A and 517B (i.e., front bit lines) are coupled to a sense amplifier 540 (i.e., a front sense amplifier). The bit lines 517C and 517D (i.e., a back bit lines) are coupled to a sense amplifier 540 (i.e., back sense amplifier). A conductive structure 535 or 545 may extend in a direction perpendicular to the memory layers 510. Each conductive structure 535 or 545 may include one or more vias, including TSVs. Memory cells in different memory layers 510 may have different memory addresses, based on which the memory cells may be located, selected, or accessed.

The bonding layer 550A is between the memory layer 510B and the CMOS layer. The bonding layer 550B is between the memory layer 510C and the CMOS layer. The bonding layers 550A and 550B may be examples of the bonding layers 130 in FIG. 1. Each of the bonding layers 550A and 550B includes conductive structures 555 (individually referred to as “conductive structure 555”) and a bonding material 557. The conductive structures 555 may be examples of the conductive structures 103. Examples of the bonding material 557 may include the bonding materials described above. For the purpose of simplicity and illustration, FIG. 5A shows some of the conductive structures in each bonding layer 550 and does not show the bonding material 557. FIG. 5B shows more details about the bonding layers 550.

As shown in FIG. 5B, each conductive structure 535 is connected to a conductive structure 555 in the bonding layer 550A and a conductive structure 555 in the bonding layer 550B. Each conductive structure 545 is connected to a conductive structure 555 in one of the bonding layers 550. In other embodiments, the conductive structures 535 or 545 may have different connections with conductive structures 555 in a bonding layer 550. One or more conductive structures 555 in a bonding layer 550 may be left unconnected to any of the conductive structures 535 or 545.

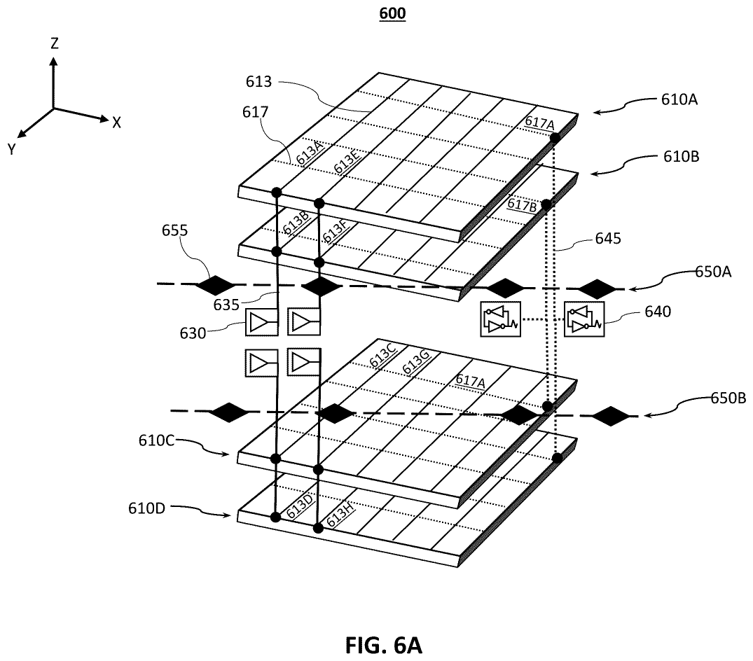

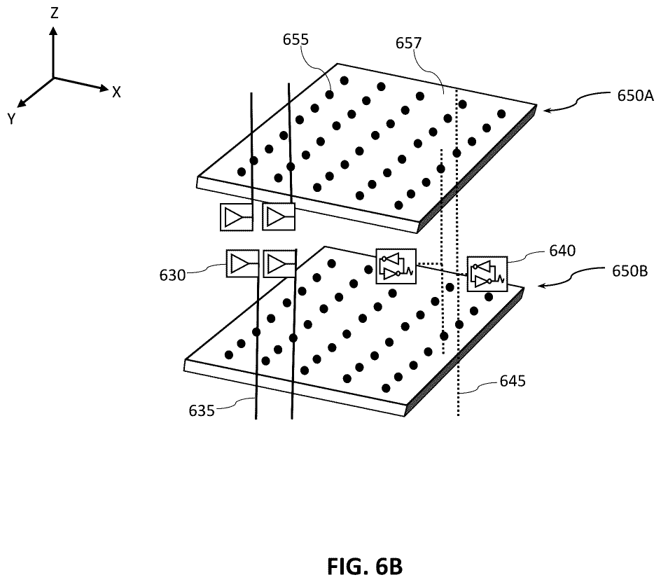

FIGS. 6A and 6B illustrates another IC device 600 with memory layers 610A-610D sharing word line drivers 630 and sense amplifiers 640 in a CMOS layer that is boned to the memory layers 610A-610D through bonding layers 630A and 630B, according to some embodiments of the present disclosure. The IC device 600 may be an example of the IC device 100 of FIG. 1. In the embodiments of FIGS. 6A and 6B, the CMOS layer is between the memory layers 610B and 610C, so that the memory layers 610A and 610B are at the frontside of the CMOS layer versus the memory layers 610C and 610D are at the backside of the CMOS layer. The four memory layers 610A-210D may be referred to as “memory layers 610” or “memory layer 610.” In other embodiments, the IC device 600 may include a different number of memory layers at either side of the CMOS layer. For the purpose of illustration, the CMOS layer is not shown in FIGS. 6A and 6B. Also, the IC device 600 may include other components that are not shown in FIGS. 6A and 6B, such as bonding layers, vias, and so on.

The CMOS layer provides power and signals to the memory layers 610. The CMOS layer may also receive signals (e.g., data stored in the memory layers 610) from the memory layers 610. The CMOS layer may be an example of the CMOS layer 120 in FIG. 1. In the embodiments of FIGS. 6A and 6B, the CMOS layer includes four word line drivers 630 (individually referred to as “word line driver 630”) and a sense amplifier 640. Even though not shown in FIGS. 6A and 6B, the CMOS layer may include other components, such as additional word line driver 630, additional sense amplifier 640, row decoders, column decoders, SRAM arrays, and so on. The word line drivers 630 may be separate from each other. In some embodiments, the word line drivers 630 are separated from each other by one or more electrical insulators.

Each memory layer 610 includes word lines 613 (individually referred to as “word line 613”) and bit lines 617 (individually referred to as “word line 613”). Each memory layer 610 may also include memory cells coupled to the word lines 613 and bit lines 617. The word lines 613 may be examples of the word lines 113 in FIG. 1, the bit lines 617 may be examples of the bit lines 117 in FIG. 1. The memory layers 610 may be examples of the memory layers 110 in FIG. 1. In some embodiments, the word lines 613 are coupled to the word line drivers 630 in the CMOS layer, and the bit lines 617 are coupled to the sense amplifiers 640 in the CMOS layer.

For the purpose of simplicity and illustration, FIGS. 6A and 6B show connections between representative word lines 613A-613H and the word line drivers 630 and connections between representative bit lines 617A-617D and sense amplifiers 640. The IC device 600 may include other connections between word lines 613 and word line drivers 630 or other connections between bit lines 617 and sense amplifiers 640. As shown in FIG. 6A, the word line 613A and bit line 617A are in the memory layer 610A; the word line 613B and bit line 617B are in the memory layer 610B; the word line 613C and bit line 617C are in the memory layer 610C; and the word line 613D and bit line 617D are in the memory layer 610D.

The IC device 600 has a “front-back word line drivers” plus “near-far” sense amplifiers arrangement. As shown in FIG. 6A, the word lines 613A and 613D (i.e., far word lines) are coupled to a word line driver 630 (i.e., a far word line driver). The word lines 613E and 613F (i.e., far word lines) are coupled to another word line driver 630 (i.e., another far word line driver). The word lines 613B and 613D (i.e., a near word lines) are coupled to another word line driver 630 (i.e., near word line driver). The word lines 613G and 613H (i.e., near word lines) are coupled to another word line driver 630 (i.e., another near word line driver). The word lines 613A-613H are coupled to the word line drivers 630 through conductive structures 635. The bit lines 617A and 617B (i.e., front bit lines) are coupled to a sense amplifier 640 (i.e., a front sense amplifier). The bit lines 617C and 617D (i.e., back bit lines) are coupled to a sense amplifier 640 (i.e., a back sense amplifier).

A conductive structure 635 or 645 may extend in a direction perpendicular to the memory layers 610. Each conductive structure 635 or 645 may include one or more vias, including TSVs. Memory cells in different memory layers 610 may have different memory addresses, based on which the memory cells may be located, selected, or accessed.

The bonding layer 650A is between the memory layer 610B and the CMOS layer. The bonding layer 650B is between the memory layer 610C and the CMOS layer. The bonding layers 650A and 650B may be examples of the bonding layers 130 in FIG. 1. Each of the bonding layers 650A and 650B includes conductive structures 655 (individually referred to as “conductive structure 655”) and a bonding material 657. The conductive structures 655 may be examples of the conductive structures 103. Examples of the bonding material 657 may include the bonding materials described above. For the purpose of simplicity and illustration, FIG. 6A shows some of the conductive structures in each bonding layer 650 and does not show the bonding material 657. FIG. 6B shows more details about the bonding layers 650.

As shown in FIG. 6B, each conductive structure 635 is connected to a conductive structure 655 in one of the bonding layers 650. Each conductive structure 645 is connected to a conductive structure 655 in the bonding layer 650A and a conductive structure 655 in the bonding layer 650B. In other embodiments, the conductive structures 635 or 645 may have different connections with conductive structures 655 in a bonding layer 650. One or more conductive structures 655 in a bonding layer 650 may be left unconnected to any of the conductive structures 635 or 645.

In some embodiments (e.g., embodiments where there are more word lines or less bitlines), the IC device 600 may have better performance than the IC device 500 in FIGS. 5A and 5B. In other embodiments (e.g., embodiments where there are less word lines or more bitlines), the IC device 500 in FIGS. 5A and 5B may have better performance than the IC device 600.

FIG. 7 illustrates an IC device 700 including a stack of wafers, according to some embodiments of the disclosure. The IC device 700 may also be referred to as an IC device or IC assembly. The stack of wafers includes wafers 712A (individually referred to as “wafer 712A”), a wafer 714, and wafers 712B (individually referred to as “wafer 712B”). The wafers 712A may be at the frontside of the wafer 714, and the wafers 712B may be at the backside of the wafer 714. The wafers 712A and 712B may be collectively referred to as “wafers 712” or “wafer 712.” In other embodiments, the IC device 700 may include fewer, more, or different components. For instance, the IC device 700 may include a different number of wafers 712A at the frontside of the wafer 714 or a different number of wafers 712B at the backside of the wafer 714.

In some embodiments, each wafer 712 may be a memory wafer. The wafers 712 may include transistors forming memory cells to implement memory arrays of the IC device 700, while the wafer 714 may include transistors forming control logic configured to control operation of (e.g., to control input/output or read/write to) the memory arrays of the memory cells of the wafers 712. The wafers 712 may be referred to as “memory wafers.” The wafer 714 may be referred to as a “logic wafer,” “compute wafer,” or “compute logic wafer.” In some embodiments, the wafer 714 may include logic circuits used to control the wafers 712-like I/O, memory scheduler etc.

Each of the wafers 712 and 714 of the IC device 700 may be composed of one or more semiconductor materials and may include one or more dies having IC structures formed on a surface of the wafers 712 and 714. Even though FIG. 7 shows three wafers 712A on one side of the wafer 714 and three wafers 712B on the other side of the wafer 714, the IC device 700 may include a different number of wafers 714 on either side of the wafer 714.

As shown in FIG. 7, each wafer 712 includes a plurality of memory dies 720 (individually referred to as “memory die 720”). A memory die 720 may be referred to as a “memory chiplet.” Examples of the memory dies 720 may include the memory layers 110, 210, 310, 410, 510, and 610. The wafer 714 includes a plurality of logic dies 730 (individually referred to as “logic die 730”). A logic die 730 may be referred to as a “compute chiplet.” Examples of the logic dies 730 may include the CMOS layer 120 in FIG. 1 and the CMOS layers in FIGS. 2-6. Each memory die 720 or logic die 710 may be a repeating unit of a semiconductor product that includes any suitable IC, e.g., an IC implementing memory, an IC implementing compute logic, etc. After the fabrication of the semiconductor product is complete, the wafers 712 and 714 may undergo a singulation process in which the memory dies 720 and the logic dies 730 are separated from one another to provide discrete “chips” of the semiconductor product.

Each memory die 720 includes a plurality of memory arrays. The memory dies 720 may be controlled by one or more logic circuits in the logic die 730. Also, the logic dies 730 may include, or otherwise be associated with, power delivery components for delivering power to the memory devices 725. For instance, a logic die 730 may include one or more power interconnects, one or more power vias, etc. The logic dies 730 may also include components that can control the memory dies 720, such as word line driver, row decoder, sense amplifier, column decoder, and so on. The logic dies 730 may transmit signals to the memory devices 725 for reading data from the memory devices 725 or writing data into the memory devices 725. In some embodiments, the logic dies 730 may include one or more processing units (e.g., central processing unit (CPU), graphics processing unit (GPU), etc.) that can generate data read or write signals, generate data to be written into memory cells in the memory dies 720, process data read from memory cells in the memory dies 720, and so on.

FIG. 8 is an electric circuit diagram of an example DRAM array 800, according to some embodiments of the present disclosure. The DRAM array 800 may be an example of memory arrays in the memory layers 110, 210, 310, 410, 510, or 610. As shown in FIG. 8, the DRAM array 800 is an array of memory cells 805-11, 805-12, 805-21, and 805-22 (collectively referred to as “memory cells 805” or “memory cell 805”), which are arranged in rows 810-1 and 810-2 (collectively referred to as “rows 810” or “row 810”) and columns 812-1 and 812-2 (collectively referred to as “columns 812” or “column 812”). Each memory cell 805 is illustrated within one of the dashed boxes in FIG. 8. Each memory cell 805 may be a DRAM cell. In other embodiments, the DRAM array 800 may include a different number of memory cells 805, a different number of rows 810, or a different number of columns 812.

The DRAM array 800 also includes three types of control lines: bit lines 840-1 and 840-2 (collectively referred to as “bit lines 840” or “bit line 840”), word lines 850-1 and 850-2 (collectively referred to as “word lines 850” or “word line 850”), and plate lines 860-1 and 860-2 (collectively referred to as “plate lines 860” or “plate line 860”), which control the memory cells 805. The memory cells 805 in the row 810-1 are coupled to the same bit line 840-1. The memory cells in the row 810-1 are coupled to the same bit line 840-2. The memory cells in the column 812-1 are coupled to the same word line 850-2 and the same plate line 860-2. The memory cells in the column 812-2 are coupled to the same word line 850-1 and the same plate line 860-1. As is conventionally used in context of memory, the terms “row” and “column” do not reflect the, respectively, horizontal and vertical orientation on a page of a drawing illustrating a memory array but, instead, reflect how individual memory cells are addressed. Namely, memory cells 805 sharing a single bit line 840 are said to be in the same row, while memory cells sharing a single word line 850 and a single plate line 860 are said to be on the same column. In other embodiments, the DRAM array 800 may include a different number of memory cells, bit lines, word lines, or plate lines. Furthermore, in other embodiments, the memory cells 805 may be arranged in arrays in a manner other than what is shown in FIG. 8, e.g., in any suitable manner of arranging memory cells into arrays as known in the art, all of which being within the scope of the present disclosure.

A memory cell 805 may store one bit of binary information. Each memory cell 805 is a 1T-1X memory cell. The memory cell 805 includes a memory element 820 and an access transistor 830. The memory element 820 is configured to store signals. The memory element 820 may have more than one state. The memory element 820 having two states may be referred to as a binary memory element. In other embodiments, the memory element 820 may have more than two states. In some embodiments, the memory element 820 is a capacitor that can store electrical voltage signals, and the memory cell 805 is a one-transistor one-capacitor (1T-1C) memory cell. In other embodiments, the memory element 820 may be, for example, a ferroelectric memory element, a magnetic storage element, a resistor, or another transistor, coupled to the access transistor 830. Also, the memory element 820 may store signals other than electrical voltage signals.

The access transistor 830 controls access to the memory cell 805. For instance, the access transistor 830 controls access to write information to the memory cell 805, access to read information from the memory cell 805, or both. The access transistor 830 has a gate terminal, a source terminal, and a drain terminal, indicated in the example of FIG. 8 as terminals G, S, and D, respectively. An embodiment of the access transistor 830 may be a vertical transistor, such as the vertical transistor 85 described above in conjunction in FIG. 1.

The access transistor 830 may be a nanowire-based or nanoribbon-based transistor (or, simply, a nanowire transistor or nanoribbon transistor). In a nanowire or nanoribbon transistor, a gate stack that may include a stack of one or more gate electrode metals and, optionally, a stack of one or more gate insulators may be provided around a portion of an elongated semiconductor structure called “nanowire or nanoribbon”, forming a gate on all sides of the nanowire or nanoribbon. The portion of the nanowire or nanoribbon around which the gate stack wraps around is referred to as a “channel” or a “channel portion.” A semiconductor material of which the channel portion of the nanoribbon is formed is commonly referred to as a “channel material.” A source region and a drain region are provided on the opposite ends of the nanowire or nanoribbon, on either side of the gate stack, forming, respectively, a source and a drain of such a transistor. Wrap-around or all-around gate transistors, such as nanoribbon and nanowire transistors, may provide advantages compared to other transistors having a non-planar architecture, such as FinFETs, and transistors having planar architecture. In the following, the terms “terminal” and “electrode” may be used interchangeably. Furthermore, for S/D terminals, the terms “terminal” and “region” may be used interchangeably.

As shown in FIG. 8, the gate terminal of the access transistor 830 is coupled to a word line 850, one of the S/D terminals of the access transistor 830 is coupled to a bit line 840, and the other one of the S/D terminals of the access transistor 830 is coupled to a first terminal of the memory element 820, e.g., a first electrode of a capacitor. As also shown in FIG. 8, the other terminal of the memory element 820 may be coupled to a capacitor plate line 860. As is known in the art, word line, bit line, and plate line may be used together to read and program the memory element 820. In some embodiments (e.g., embodiments where the access transistor 830 is the vertical transistor 85), a portion of the bit line 840 may be a S/D region of the access transistor 830. Another S/D region of the access transistor 830 is coupled to the memory element 820. Also, a portion of the word line 850 may be a gate electrode of the access transistor 830. Such vertical transistors can improve the memory cell density of the DRAM array 800 so that more memory cells can be arranged in the available space of the DRAM array 800.

Each of the bit line 840, the word line 850, and the plate line 860, as well as intermediate elements coupling these lines to various terminals described herein, may be formed of any suitable electrically conductive material, which may include an alloy or a stack of multiple electrically conductive materials. In some embodiments, such electrically conductive materials may include one or more metals or metal alloys, with metals such as ruthenium, palladium, platinum, cobalt, nickel, hafnium, zirconium, titanium, tantalum, and aluminum. In some embodiments, such electrically conductive materials may include one or more electrically conductive alloys oxides or carbides of one or more metals.

In the embodiment of FIG. 8, a single plate line 860 is shared among multiple memory cells 805 of a given row. The plate lines 860 are shared among the same memory cells 805 among which the word line 850 are shared. Such an arrangement where the plate lines 860 are shared among the same memory cells among which the word lines 850 are shared may be described as an arrangement where the plate lines 860 are “parallel” to the word lines 850. Each memory cell 805 of the DRAM array 800 where the plate lines 860 are parallel to the word lines 850, e.g., as shown in FIG. 8, may then be addressed (e.g., to perform READ and WRITE operations) by using the word line 850 and the plate line 860 corresponding to the column 812 to which the memory cell 805 belongs and by using the bit line 840 corresponding to the row 810 to which the memory cell 805 belongs.

It should be noted that, just as the horizontal and vertical orientations on a page of an electrical circuit diagram illustrating a memory array does imply functional division of memory cells into rows and columns as used in common language, the orientation of various elements on a page of an electrical circuit diagram illustrating a memory array does not imply that the same orientation is used for the actual physical layout of a memory array. For example, in an IC device implementing the DRAM array 800 as shown in FIG. 2A, corresponding bit lines 840 and plate lines 860 (i.e., a pair of a bit line 840 and a plate line 860 coupled to a given column 812) do not have to physically extend in a direction parallel to one another (although they may), or the word lines 850 do not have to physically extend in a direction perpendicular to the bit lines 840 (although they may). In another example, in an IC device implementing the DRAM array 800 as shown in FIG. 8, corresponding word lines 850 and plate lines 860 (i.e., a pair of a word line 850 and a plate line 860 coupled to a given column 812) do not have to physically extend in a direction parallel to one another (although they may), or the word lines 850 do not have to physically extend in a direction perpendicular to the bit lines 840 (although they may).

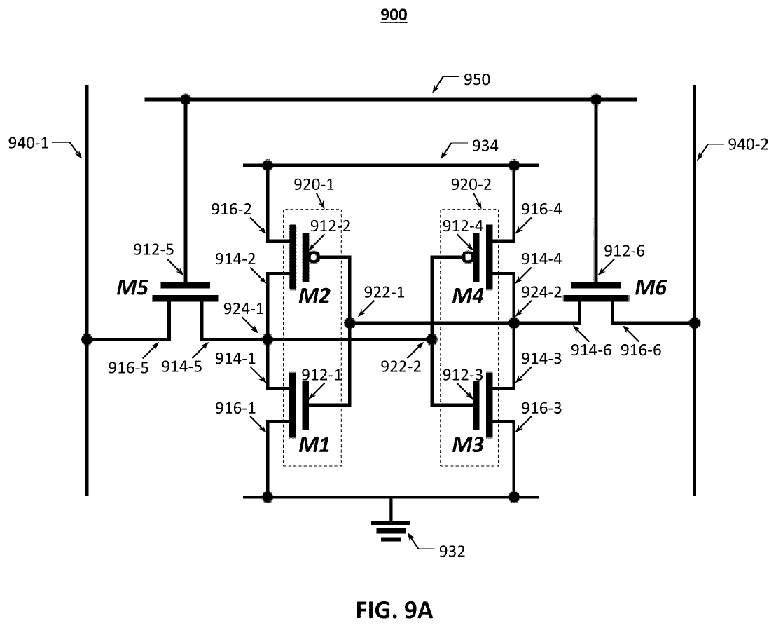

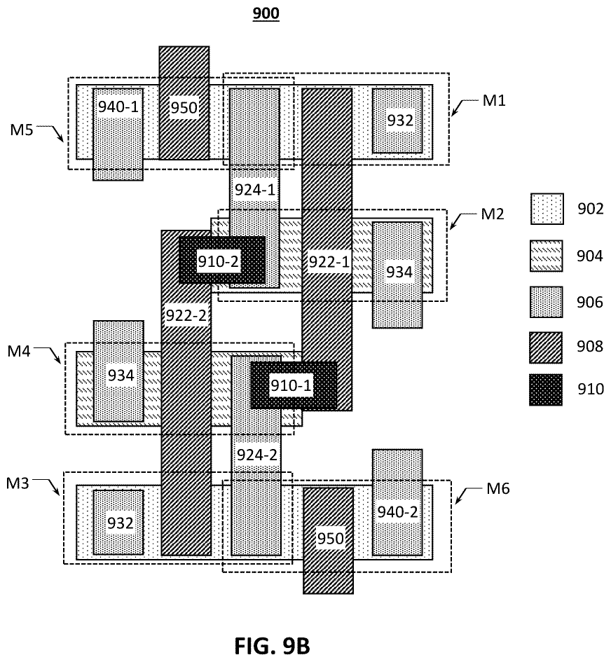

FIG. 9A is an electric circuit diagram of an example SRAM cell 900, according to some embodiments of the present disclosure. The SRAM cell 900 may be in a CMOS layer, such as the CMOS layer 120 in FIG. 1 or the CMOS layers in FIGS. 2-6. In some embodiments, the SRAM cell 900 may be used in an SRAM array. As shown in FIG. 9B, the SRAM cell 900 includes transistors M1-M4 for storing a bit value or a memory state (e.g., logic “1” or “0”) of the cell, and two access transistors, M5 and M6, for controlling access to the cell (e.g., access to write information to the cell or access to read information from the SRAM cell 900). The SRAM cell 900 is a 6-transistor (6T) memory cell. In other embodiments, the SRAM cell 900 may include a different number of transistors. Each of the transistors M1-M6 may have any transistor architecture, such as planar or non-planar (e.g., FinFET, nanoribbon/nanowire, etc.).

In the SRAM cell 900, each bit may be stored on four transistors (M1, M2, M3, M4) that form two cross-coupled inverters 920, each having an input 922 and an output 924. The first inverter 920-1 may be formed by an NMOS transistor M1 and a PMOS transistor M2, while the second inverter 920-2 may be formed by an NMOS transistor M3 and a PMOS transistor M4. As shown in FIG. 9B, the gate stack 912-1 of the transistor M1 may be coupled to the gate stack 912-2 of the transistor M2, and both of these gate stacks may be coupled to the input 922-1 of the first inverter 920-1. On the other hand, the first S/D region 914-1 of the transistor M1 may be coupled to the first S/D region 914-2 of the transistor M2, and both of these first S/D regions 914-1 and 914-2 may be coupled to the output 924-1 of the first inverter 920-1. Similarly, for the second inverter 920-2, the gate stack 912-3 of the transistor M3 may be coupled to the gate stack 912-4 of the transistor M4, and both of these gate stacks may be coupled to the input 922-2 of the second inverter 920-2, while the first S/D region 914-3 of the transistor M3 may be coupled to the first S/D region 914-4 of the transistor M4, and both of these first S/D regions 914-3 and 914-4 may be coupled to the output 924-2 of the second inverter 920-2. As also shown in FIG. 9B, when the transistors M1 and M3 are NMOS transistors and when the transistors M2 and M4 are PMOS transistors as illustrated in FIG. 9B, the second S/D regions 916-1 and 916-3 of the transistors M1 and M3 may be coupled to a ground voltage 932, while the second S/D regions 916-2 and 916-4 of the transistors M2 and M4 may be coupled to a supply voltage 934, e.g., VDD. In the embodiments of the SRAM cell 900 where the NMOS transistors shown in FIG. 9B are replaced with PMOS transistors and vice versa, the designation of the ground voltage 932 and the supply voltage 934 would be reversed as well, all of which embodiments being within the scope of the present disclosure.

The four transistors M1-M4 in such configuration form a stable storage cell for storing a bit value of 0 or 1. Two additional access transistors, M5 and M6, may serve to control the access to the storage cell of the transistors M1-M4 during read and write operations. The first S/D region 914-5 of the access transistor M5 may be coupled to the output 924-1 of the first inverter 920-1. Phrased differently, the first S/D region 914-5 of the access transistor M5 may be coupled to each of the first S/D region 914-1 of the transistor M1 and the first S/D region 914-2 of the transistor M2. The second S/D region 916-5 of the access transistor M5 may be coupled to a first bit line 940-1. Thus, each of the first S/D region 914-1 of the transistor M1 and the first S/D region 914-2 of the transistor M2 may be coupled to the first bit line 940-1 (e.g., via the access transistor M5). The gate 912-5 of the access transistor M5 may be coupled to a word line 950.

The first S/D region 914-6 of the access transistor M6 may be coupled to the output 924-2 of the second inverter 920-2. Phrased differently, the first S/D region 914-6 of the access transistor M6 may be coupled to each of the first S/D region 914-3 of the transistor M3 and the first S/D region 914-4 of the transistor M4. The second S/D region 916-6 of the access transistor M6 may be coupled to a second bit line 940-2. Thus, each of the first S/D region 914-3 of the transistor M3 and the first S/D region 914-4 of the transistor M4 may be coupled to the second bit line 940-2 (e.g., via the access transistor M6). The gate 912-6 of the access transistor M6 may be coupled to the word line 950. Thus, the gates 912-5 and 912-6 of both of the access transistors M5 and M6 may be coupled to a single, shared, word line, the word line 950.

The input 922-1 of the first inverter 920-1 may be coupled to the first S/D region 914-6 of the access transistor M6, while the input 922-2 of the second inverter 920-2 may be coupled to the first S/D region 914-5 of the access transistor M5. In other words, each of the gate stack 912-1 of the transistor M1 and the gate stack 912-2 of the transistor M2 may be coupled to the first S/D region 914-6 of the access transistor M6, while each of the gate stack 912-3 of the transistor M3 and the gate stack 912-4 of the transistor M4 may be coupled to the first S/D region 914-5 of the access transistor M5. Phrased differently, each of the gate stack 912-1 of the transistor M1 and the gate stack 912-2 of the transistor M2 may be coupled to the second bit line 940-2 (e.g., via the access transistor M6), while each of the gate stack 912-3 of the transistor M3 and the gate stack 912-4 of the transistor M4 may be coupled to the first bit line 940-1 (e.g., via the access transistor M5).

The word line 950 and the first and second bit lines 940 may be used together to read and program (i.e., write to) the SRAM cell 900. In particular, access to the cell may be enabled by the word line 950 which controls the two access transistors M5 and M6 which, in turn, control whether the SRAM cell 900 should be connected to the bit lines 940-1 and 940-2. During operation of the SRAM cell 900, a signal on the first bit line 940-1 may be complementary to a signal on the second bit line 940-2. The two bit lines 940 may be used to transfer data for both read and write operations. In other embodiments of the SRAM cell 900, only a single bit line 940 may be used, instead of two bitlines 940-1 and 940-2, although having one signal bit line and one inverse, such as the two bit lines 940, may help improve noise margins.

During read accesses, the bit lines 940 are actively driven high and low by the inverters 920 in the SRAM cell 900. This may improve SRAM bandwidth compared to DRAM. The symmetric structure of the SRAM cell 900 also allows for differential signaling, which may provide an improvement in detecting small voltage swings. Another difference with DRAM that may contribute to making SRAM faster than DRAM is that commercial chips accept all address bits at a time. By comparison, commodity DRAMs may have the address multiplexed in two halves, i.e. higher bits followed by lower bits, over the same package pins in order to keep their size and cost down.

Each of the word line 950 and the bit lines 940, as well as intermediate elements coupling these lines to various terminals described herein, may be formed of any suitable electrically conductive material, which may include an alloy or a stack of multiple electrically conductive materials. In some embodiments, such electrically conductive materials may include one or more metals or metal alloys, with metals such as ruthenium, palladium, platinum, cobalt, nickel, hafnium, zirconium, titanium, tantalum, and aluminum. In some embodiments, such electrically conductive materials may include one or more electrically conductive alloys oxides or carbides of one or more metals.

FIG. 9B provides a top-down plan view of an example implementation of the SRAM cell 900, according to some embodiments of the present disclosure. FIG. 9B illustrates how the six transistors M1-M6 shown in FIG. 9A may be implemented. Several elements from FIG. 9A are labelled in FIG. 9B. For example, the transistors M1-M6 are labelled in FIG. 9B, with the approximate boundaries of the individual transistors shown in FIG. 9B with dashed rectangles. Certain elements, e.g., the specific S/D regions 914 and 916 and the gate stacks 912, are not labelled in FIG. 9B for the purpose of simplicity and illustration.

FIG. 9B illustrates that transistors M1 and M5 may be provided along a first region of an N-type semiconductor 902, transistors M2 and M4 may each be provided along a respective first and second region of a P-type semiconductor 904, and the transistors M4 and M6 may be provided along a second region of the N-type semiconductor 902. Each of the regions of the N-type semiconductor 902 and P-type semiconductor 904 may be formed in a support structure (e.g., a substrate) or over a support structure, e.g., as a fin or nanoribbon. The N-type semiconductor 902 is suitable for forming transistors of a first type, e.g., NMOS transistors, while the P-type semiconductor 904 is suitable for forming transistors of a second type, e.g., PMOS transistors, thus realizing NMOS transistors M1, M3, M5, and M6, and PMOS transistors M2 and M4, as shown in FIG. 9B.

In the plan view shown in FIG. 9B, S/D contacts 906, gate electrodes 908, and interconnects 910 are formed over the N-type and P-type semiconductors 902 and 904, e.g., as layers processed over the N-type and P-type semiconductors 902 and 904. While not specifically shown in FIG. 9B, S/D regions may be formed under the S/D contacts 906, and gate dielectrics may be formed under the gate electrodes 908. Any of the materials and processes described with respect to FIG. 4 may be used to form the transistors shown in FIG. 9B.

More specifically, a shared gate stack may be used to realize the gate stack 912-1 of the transistor M1 coupled to the gate stack 912-2 of the transistor M2. The shared gate stack is labelled 922-1 in FIG. 9B, representing a node that is the input 922-1 of the first inverter 920-1 of the SRAM cell 900. Similarly, a shared gate stack may be used to realize the gate stack 212-3 of the transistor M3 coupled to the gate stack 212-4 of the transistor M4 3. The shared gate stack is labelled 922-2 in FIG. 9B, representing a node that is the input 922-2 of the second inverter 920-2 of the SRAM cell 900.

A first shared S/D contact may be used to realize the first S/D region 914-1 of the transistor M1 coupled to the first S/D region 914-2 of the transistor M2. The first shared S/D contact is labelled 924-1 in FIG. 9B, representing a node that is the output 924-1 of the first inverter 920-1 of the SRAM cell 900. Similarly, a second shared S/D contact may be used to realize the first S/D region 914-3 of the transistor M3 coupled to the first S/D region 914-4 of the transistor M4. The first shared S/D contact is labelled 924-2 in FIG. 9B, representing a node that is the output 924-2 of the second inverter 920-2 of the SRAM cell 900.

A first interconnect 910-1 may then be used to couple the shared gate stack 922-1 of the first inverter 920-1 to the shared S/D contact 924-2 of the second inverter 920-2, thus realizing the coupling of the input 922-1 of the first inverter 920-1 to the output 924-2 of the second inverter 920-2, shown in FIG. 9B. Similarly, a second interconnect 910-2 may then be used to couple the shared gate stack 922-2 of the second inverter 920-2 to the shared interconnect 924-1 of the first inverter 920-1, thus realizing the coupling of the input 922-2 of the second inverter 920-2 to the output 924-1 of the first inverter 920-1.

In a given SRAM cell 900, the first S/D region 914-5 of the transistor M5 may be shared with (e.g., be the same as) the first S/D region 914-1 of the transistor M1 (since both of these transistors are implemented in a single region of the N-type semiconductor 902). In addition, the first S/D region 914-3 of the transistor M3 may be shared with (e.g., be the same as) the first S/D region 914-6 of the transistor M6 (since both of these transistors are implemented in a single region of the N-type semiconductor 902).

Both of the second S/D region 916-1 of the transistor M1 and the second S/D region 916-3 of the transistor M3 may be coupled to the ground voltage 932, as was described with reference to FIG. 9B. Both of the second S/D region 916-2 of the transistor M2 and the second S/D region 916-4 of the transistor M4 may be coupled to the supply voltage 934, as was described with reference to FIG. 9B.

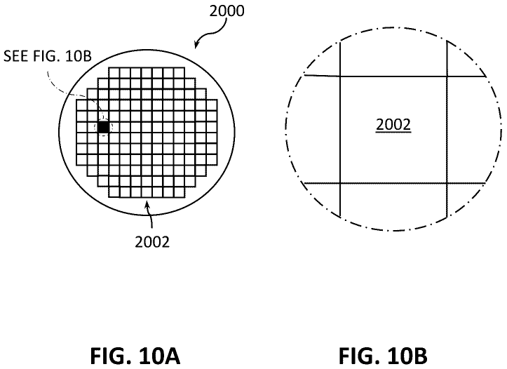

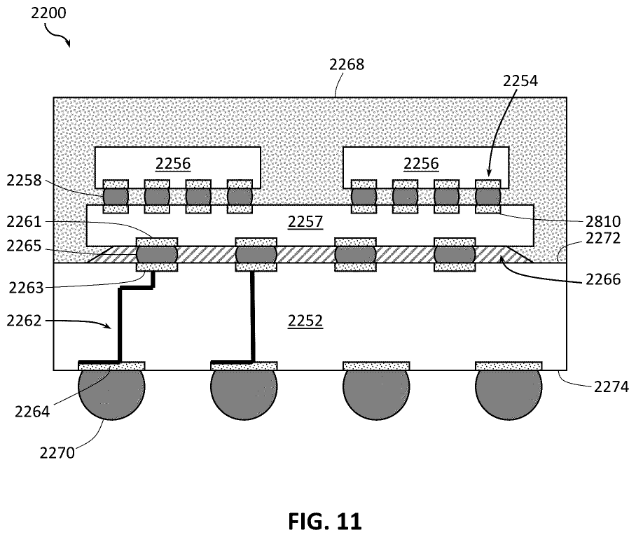

FIGS. 10A and 10B are top views of a wafer 2000 and dies 2002 that can facilitate stacked memory layers with bit lines and word lines connected to a CMOS layer, according to some embodiments of the disclosure. In some embodiments, the dies 2002 may be included in an IC package, according to some embodiments of the disclosure. For example, any of the dies 2002 may serve as any of the dies 2256 in an IC package 2200 shown in FIG. 11. The wafer 2000 may be composed of semiconductor material and may include one or more dies 2002 having IC devices formed on a surface of the wafer 2000. Each of the dies 2002 may be a repeating unit of a semiconductor product that includes any suitable IC. After the fabrication of the semiconductor product is complete (e.g., after manufacture of metal lines as described herein), the wafer 2000 may undergo a singulation process in which each of the dies 2002 is separated from one another to provide discrete “chips” of the semiconductor product. In particular, devices that include stacked memory layers with bit lines and word lines connected to a CMOS layer as disclosed herein may take or include components that take the form of the wafer 2000 (e.g., not singulated) or the form of the die 2002 (e.g., singulated). The die 2002 may include one or more diodes, one or more transistors (e.g., one or more III-N transistors as described herein) as well as, optionally, supporting circuitry to route electrical signals to the III-N diodes with n-doped wells and capping layers and III-N transistors, as well as any other IC components. In some embodiments, the wafer 2000 or the die 2002 may implement an electrostatic discharge (ESD) protection device, a radio frequency front-end device, a memory device (e.g., a SRAM device), a logic device (e.g., an AND, OR, NAND, or NOR gate), or any other suitable circuit element. Multiple ones of these devices may be combined on a single die 2002.

FIG. 11 is a side, cross-sectional view of an example IC package 2200 that may include stacked memory layers with bit lines and word lines connected to a CMOS layer, according to some embodiments of the disclosure. In some embodiments, the IC package 2200 may be a system-in-package (SiP). As shown in FIG. 11, the IC package 2200 may include a package substrate 2252. The package substrate 2252 may be formed of a dielectric material (e.g., a ceramic, a glass, a combination of organic and inorganic materials, a buildup film, an epoxy film having filler particles therein, etc., and may have embedded portions having different materials), and may have conductive pathways extending through the dielectric material between the face 2272 and the face 2274, or between different locations on the face 2272, and/or between different locations on the face 2274.

The package substrate 2252 may include conductive contacts 2263 that are coupled to conductive pathways 2262 through the package substrate 2252, allowing circuitry within the dies 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 11 are solder bumps, but any suitable first-level interconnects 2265 may be used. In some embodiments, no interposer 2257 may be included in the IC package 2200; instead, the dies 2256 may be coupled directly to the conductive contacts 2263 at the face 2272 by first-level interconnects 2265.

The IC package 2200 may include one or more dies 2256 coupled to the interposer 2257 via conductive contacts 2254 of the dies 2256, first-level interconnects 2258, and conductive contacts 2260 of the interposer 2257. The conductive contacts 2260 may be coupled to conductive pathways (not shown) through the interposer 2257, allowing circuitry within the dies 2256 to electrically couple to various ones of the conductive contacts 2261 (or to other devices included in the interposer 2257, not shown). The first-level interconnects 2258 illustrated in FIG. 11 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

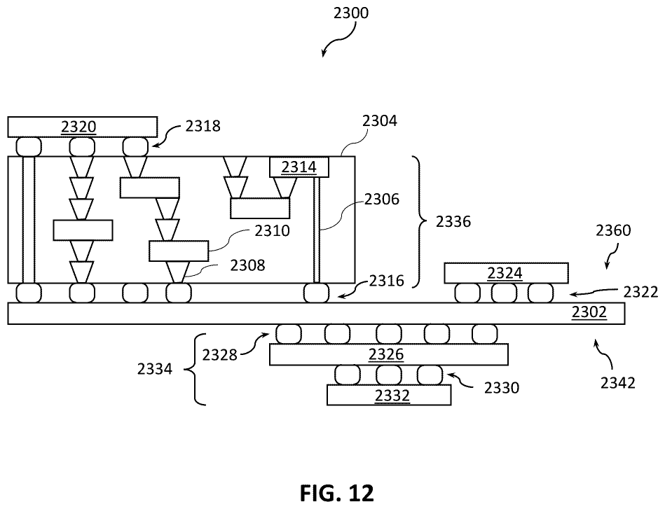

In some embodiments, an underfill material 2266 may be disposed between the package substrate 2252 and the interposer 2257 around the first-level interconnects 2265, and a mold compound 2268 may be disposed around the dies 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 11 are solder balls (e.g., for a ball grid array (BGA) arrangement), but any suitable second-level interconnects 22770 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 12.

The dies 2256 may take the form of any of the embodiments of the die 2002 discussed herein and may include any of the embodiments of an IC device with stacked memory layers with bit lines and word lines connected to a CMOS layer. In embodiments in which the IC package 2200 includes multiple dies 2256, the IC package 2200 may be referred to as a multi-chip package. Importantly, even in such embodiments of an MCP implementation of the IC package 2200, one or more IC devices with stacked memory layers with bit lines and word lines connected to a CMOS layer may be provided in a single chip, in accordance with any of the embodiments described herein. The dies 2256 may include circuitry to perform any desired functionality. For example, one or more of the dies 2256 may be ESD protection dies, one or more of the dies 2256 may be logic dies (e.g., silicon-based dies), one or more of the dies 2256 may be memory dies (e.g., high bandwidth memory), etc.

The IC package 2200 illustrated in FIG. 11 may be a flip chip package, although other package architectures may be used. For example, the IC package 2200 may be a BGA package, such as an embedded wafer-level BGA package. In another example, the IC package 2200 may be a wafer-level chip scale package or a panel fan-out package. Although two dies 2256 are illustrated in the IC package 2200 of FIG. 11, an IC package 2200 may include any desired number of the dies 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

FIG. 12 is a cross-sectional side view of an IC device assembly 2300 that may include components having stacked memory layers with bit lines and word lines connected to a CMOS layer, according to some embodiments of the disclosure. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. In particular, any suitable ones of the components of the IC device assembly 2300 may include stacked memory layers with bit lines and word lines connected to a CMOS layer in accordance with any of the embodiments disclosed herein; e.g., any of the IC packages discussed below with reference to the IC device assembly 2300 may take the form of any of the embodiments of the IC package 2200 discussed above with reference to FIG. 11 (e.g., may include stacked memory layers with bit lines and word lines connected to a CMOS layer).

In some embodiments, the circuit board 2302 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 12 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302, and may include solder balls (e.g., as shown in FIG. 11), male and female portions of a socket, an adhesive, an underfill material, and/or any other suitable electrical and/or mechanical coupling structure.

The package-on-interposer structure 2336 may include an IC package 2320 coupled to an interposer 2304 by coupling components 2318. The coupling components 2318 may take any suitable form for the application, such as the forms discussed above with reference to the coupling components 2316. The IC package 2320 may be or include, for example, a die (the die 2002 of FIG. 10B), an IC device (e.g., the IC device 100, 200, 300, 400, 500, or 600), or any other suitable component. In particular, the IC package 2320 may include stacked memory layers with bit lines and word lines connected to a CMOS layer as described herein. Although a single IC package 2320 is shown in FIG. 12, multiple IC packages may be coupled to the interposer 2304; indeed, additional interposers may be coupled to the interposer 2304. The interposer 2304 may provide an intervening substrate used to bridge the circuit board 2302 and the IC package 2320. Generally, the interposer 2304 may spread a connection to a loose pitch or reroute a connection to a different connection. For example, the interposer 2304 may couple the IC package 2320 (e.g., a die) to a BGA of the coupling components 2316 for coupling to the circuit board 2302. In the embodiment illustrated in FIG. 12, the IC package 2320 and the circuit board 2302 are attached to opposing sides of the interposer 2304; in other embodiments, the IC package 2320 and the circuit board 2302 may be attached to a same side of the interposer 2304. In some embodiments, three or more components may be interconnected by way of the interposer 2304.

The interposer 2304 may be formed of an epoxy resin, a fiberglass-reinforced epoxy resin, a ceramic material, or a polymer material such as polyimide. In some implementations, the interposer 2304 may be formed of alternate rigid or flexible materials that may include the same materials described above for use in a semiconductor substrate, such as silicon, germanium, and other group III-V and group IV materials. The interposer 2304 may include metal interconnects 2308 and vias 2310, including but not limited to TSVs 2306. The interposer 2304 may further include embedded devices 2314, including both passive and active devices. Such devices may include, but are not limited to, capacitors, decoupling capacitors, resistors, inductors, fuses, diodes, transformers, sensors, ESD protection devices, and memory devices. More complex devices such as further radio frequency (RF) devices, power amplifiers, power management devices, antennas, arrays, sensors, and microelectromechanical systems (MEMS) devices may also be formed on the interposer 2304. In some embodiments, stacked memory layers with bit lines and word lines connected to a CMOS layer as described herein may also be implemented in/on the interposer 2304. The package-on-interposer structure 2336 may take the form of any of the package-on-interposer structures known in the art.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 12 includes a package-on-package structure 2334 coupled to the second face 2342 of the circuit board 2302 by coupling components 2328. The package-on-package structure 2334 may include an IC package 2326 and an IC package 2332 coupled together by coupling components such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

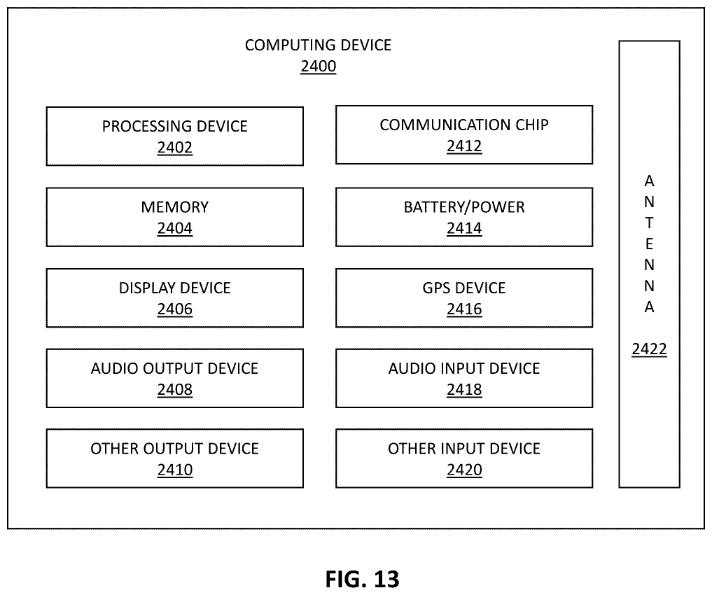

FIG. 13 is a block diagram of an example computing device 2400 that may include one or more components with stacked memory layers with bit lines and word lines connected to a CMOS layer, according to some embodiments of the disclosure. For example, any suitable ones of the components of the computing device 2400 may include one or more dies (e.g., the die 2002 of FIG. 10B) that can facilitate stacked memory layers with bit lines and word lines connected to a CMOS layer, according to some embodiments of the disclosure. Any of the components of the computing device 2400 may include an IC device (e.g., the IC device 100, 200, 300, 400, 500, or 600) and/or an IC package (e.g., the IC package 2200 of FIG. 11). Any of the components of the computing device 2400 may include an IC device assembly (e.g., the IC device assembly 2300 of FIG. 12).

A number of components are illustrated in FIG. 13 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single SoC (system-on-chip) die.

Additionally, in various embodiments, the computing device 2400 may not include one or more of the components illustrated in FIG. 13, but the computing device 2400 may include interface circuitry for coupling to the one or more components. For example, the computing device 2400 may not include a display device 2406, but may include display device interface circuitry (e.g., a connector and driver circuitry) to which a display device 2406 may be coupled. In another set of examples, the computing device 2400 may not include an audio input device 2418 or an audio output device 2408, but may include audio input or output device interface circuitry (e.g., connectors and supporting circuitry) to which an audio input device 2418 or audio output device 2408 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific ICs (ASICs), CPUs, GPUs, cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), nonvolatile memory (e.g., read-only memory (ROM)), flash memory, solid-state memory, and/or a hard drive. In some embodiments, the memory 2404 may include memory that shares a die with the processing device 2402. This memory may be used as cache memory and may include, e.g., eDRAM, and/or spin transfer torque magnetic random-access memory (STT-MRAM).

In some embodiments, the computing device 2400 may include a communication chip 2412 (e.g., one or more communication chips). For example, the communication chip 2412 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2412 may operate in accordance with other wireless protocols in other embodiments. The computing device 2400 may include an antenna 2422 to facilitate wireless communications and/or to receive other wireless communications (such as AM or FM radio transmissions).

In some embodiments, the communication chip 2412 may manage wired communications, such as electrical, optical, or any other suitable communication protocols (e.g., the Ethernet). As noted above, the communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

In various embodiments, IC devices as described herein may be particularly advantageous for use as part of ESD circuits protecting power amplifiers, low-noise amplifiers, filters (including arrays of filters and filter banks), switches, or other active components. In some embodiments, IC devices as described herein may be used in PMICs, e.g., as a rectifying diode for large currents. In some embodiments, IC devices as described herein may be used in audio devices and/or in various input/output devices.

The computing device 2400 may include battery/power circuitry 2414. The battery/power circuitry 2414 may include one or more energy storage devices (e.g., batteries or capacitors) and/or circuitry for coupling components of the computing device 2400 to an energy source separate from the computing device 2400 (e.g., AC line power).

The computing device 2400 may include a display device 2406 (or corresponding interface circuitry, as discussed above). The display device 2406 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2408 (or corresponding interface circuitry, as discussed above). The audio output device 2408 may include any device that generates an audible indicator, such as speakers, headsets, or earbuds, for example.

The computing device 2400 may include an audio input device 2418 (or corresponding interface circuitry, as discussed above). The audio input device 2418 may include any device that generates a signal representative of a sound, such as microphones, microphone arrays, or digital instruments (e.g., instruments having a musical instrument digital interface (MIDI) output).

The computing device 2400 may include a GPS device 2416 (or corresponding interface circuitry, as discussed above). The GPS device 2416 may be in communication with a satellite-based system and may receive a location of the computing device 2400, as known in the art.

The computing device 2400 may include another output device 2410 (or corresponding interface circuitry, as discussed above). Examples of the other output device 2410 may include an audio codec, a video codec, a printer, a wired or wireless transmitter for providing information to other devices, or an additional storage device.

The computing device 2400 may include another input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

The following paragraphs provide various examples of the embodiments disclosed herein.

Example 1 provides an integrated circuit (IC) device, including a logic layer including a word line driver; a first memory layer at a first side of the logic layer, the first memory layer including first memory cells and a first word line coupled to the first memory cells; and a second memory layer at a second side of the logic layer, the second memory layer including second memory cells and a second word line coupled to the second memory cells, in which the second side opposes the first side, and the first word line and the second word line are coupled to the word line driver.

Example 2 provides the IC device according to example 1, in which: the logic layer further includes a first sense amplifier and a second sense amplifier, the first memory layer further includes a first bit line coupled to the first sense amplifier, and the second memory layer further includes a second bit line coupled to the second sense amplifier that is separate from the first sense amplifier.

Example 3 provides the IC device according to example 2, in which the first bit line is separated from the second bit line by an electrical insulator.

Example 4 provides the IC device according to any one of examples 1-3, in which: the logic layer further includes a second word line driver, the first memory layer further includes a third word line coupled to the second word line driver, the second memory layer further includes a fourth word line coupled to the second word line driver, and the third word line is coupled to the fourth word line.

Example 5 provides the IC device according to any one of examples 1-4, in which: the first memory layer further includes a memory cell coupled to the first word line, the memory cell includes a transistor and a capacitor, the transistor includes a channel region and an electrode over the channel region, and the first word line is coupled to the electrode.

Example 6 provides the IC device according to any one of examples 1-5, in which the logic layer includes a P-type metal-oxide-semiconductor transistor and a N-type metal-oxide-semiconductor transistor.

Example 7 provides the IC device according to any one of examples 1-6, further including a third memory layer at the first side or the second side of the logic layer, the third memory layer including a third word line; a conductive structure between the first word line and the third word line, in which the third word line is coupled to the first word line through the conductive structure.

Example 8 provides an integrated circuit (IC) device, including a logic layer including a sense amplifier; a first memory layer at a first side of the logic layer, the first memory layer including first memory cells and a first bit line coupled to the first memory cells; and a second memory layer at a second side of the logic layer, the second memory layer including second memory cells and a second bit line coupled to the second memory cells, in which the second side opposes the first side, and the first bit line and the second bit line are coupled to the sense amplifier.

Example 9 provides the IC device according to example 8, in which: the logic layer further includes a first word line driver and a second word line driver, the first memory layer further includes a first word line coupled to the first word line driver, and the second memory layer further includes a second word line coupled to the second word line driver that is separate from the first word line driver.

Example 10 provides the IC device according to example 9, in which the first word line is separated from the second word line by an electrical insulator.

Example 11 provides the IC device according to any one of examples 8-10, further including a bonding layer between the logic layer and the first memory layer, in which the bonding layer includes conductive structures, an individual conductive structure is coupled to the first bit line, and a pitch of the conductive structures is approximately 100 nanometers to 15 micrometers.

Example 12 provides the IC device according to any one of examples 8-11, in which: an individual first memory cell includes a transistor and a capacitor, the transistor includes a source region, a drain region, and an electrode over the source region or drain region, and the first bit line is coupled to the electrode.

Example 13 provides the IC device according to any one of examples 8-12, in which the logic layer includes a P-type metal-oxide-semiconductor transistor and a N-type metal-oxide-semiconductor transistor.

Example 14 provides the IC device according to any one of examples 8-13, further including a third memory layer at the first side or the second side of the logic layer, the third memory layer including a third bit line, in which the third bit line is coupled to the sense amplifier.

Example 15 provides an integrated circuit (IC) device, including a logic layer including a first sense amplifier and a second sense amplifier; a first memory layer at a first side of the logic layer, the first memory layer including first memory cells and a first bit line coupled to the first memory cells; and a second memory layer at the first side of the logic layer, the second memory layer including second memory cells and a second bit line coupled to the second memory cells; a third memory layer at a second side of the logic layer, the third memory layer including third memory cells and a third bit line coupled to the third memory cells, in which the first memory layer is between the second memory layer and the logic layer, the second side opposes the first side, the first bit line and the third bit line are coupled to the first sense amplifier, and the second bit line are coupled to the second sense amplifier that is separate from the first sense amplifier.

Example 16 provides the IC device according to example 15, further including a fourth

memory layer at a second side of the logic layer, the fourth memory layer including fourth memory cells and a fourth bit line coupled to the fourth memory cells, in which the third memory layer is between the fourth memory layer and the logic layer, and the fourth bit line is coupled to the second sense amplifier.

Example 17 provides the IC device according to example 15 or 16, in which: the first memory layer further includes a first word line coupled to the first memory cells, the second memory layer further includes a second word line coupled to the second memory cells, the third memory layer further includes a third word line coupled to the third memory cells, the logic layer further includes a first word line driver and a second word line driver that is separate from the first word line driver, the first word line and the second word line are coupled to the first word line driver, and the third word line is coupled to the second word line driver.

Example 18 provides the IC device according to example 17, further including a fourth memory layer at a second side of the logic layer, the fourth memory layer including fourth memory cells and a fourth word line coupled to the fourth memory cells, in which the third memory layer is between the fourth memory layer and the logic layer, and the fourth word line is coupled to the second word line driver.

Example 19 provides the IC device according to any one of examples 15-18, further including a bonding layer between the logic layer and the first memory layer, in which the bonding layer includes conductive structures, an individual conductive structure is coupled to the first bit line, and a pitch of the conductive structures is approximately 100 nanometers to 15 micrometers.

Example 20 provides the IC device according to any one of examples 15-19, in which the logic layer includes a P-type metal-oxide-semiconductor transistor and a N-type metal-oxide-semiconductor transistor.

Example 21 provides an IC package, including the IC device any one of examples 1-20; and a further IC component, coupled to the IC device.

Example 22 provides the IC package according to example 21, where the further IC component includes one of a package substrate, an interposer, or a further IC die.

Example 23 provides the IC package according to example 21 or 22, where the IC device may include, or be a part of, at least one of a memory device, a computing device, a wearable device, a handheld electronic device, and a wireless communications device.

Example 24 provides an electronic device, including a carrier substrate; and the IC package according to any one of examples 21-23, coupled to the carrier substrate.

Example 25 provides the electronic device according to example 24, where the carrier substrate is a motherboard.

Example 26 provides the electronic device according to example 24, where the carrier substrate is a PCB.

Example 27 provides the electronic device according to any one of examples 24-26, where the electronic device is a wearable electronic device or handheld electronic device.

Example 28 provides the electronic device according to any one of examples 24-27, where the electronic device further includes one or more communication chips and an antenna.

Example 29 provides the electronic device according to any one of examples 24-28, where the electronic device is an RF transceiver.

Example 30 provides the electronic device according to any one of examples 24-28, where the electronic device is one of a switch, a power amplifier, a low-noise amplifier, a filter, a filter bank, a duplexer, an upconverter, or a downconverter of an RF communications device, e.g., of an RF transceiver.

Example 31 provides the electronic device according to any one of examples 24-30, where the electronic device is a computing device.

Example 32 provides the electronic device according to any one of examples 24-31, where the electronic device is included in a base station of a wireless communication system.

Example 33 provides the electronic device according to any one of examples 24-31, where the electronic device is included in a user equipment device of a wireless communication system.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) device, comprising:
a logic layer comprising a word line driver;
a first memory layer at a first side of the logic layer, the first memory layer comprising first memory cells and a first word line coupled to the first memory cells; and
a second memory layer at a second side of the logic layer, the second memory layer comprising second memory cells and a second word line coupled to the second memory cells,
wherein the second side opposes the first side, and the first word line and the second word line are coupled to the word line driver.

2. The IC device according to claim 1, wherein:
the logic layer further comprises a first sense amplifier and a second sense amplifier,
the first memory layer further comprises a first bit line coupled to the first sense amplifier, and
the second memory layer further comprises a second bit line coupled to the second sense amplifier that is separate from the first sense amplifier.

3. The IC device according to claim 2, wherein the first bit line is separated from the second bit line by an electrical insulator.

4. The IC device according to claim 1, wherein:
the logic layer further comprises a second word line driver,
the first memory layer further comprises a third word line coupled to the second word line driver,
the second memory layer further comprises a fourth word line coupled to the second word line driver, and
the third word line is coupled to the fourth word line.

5. The IC device according to claim 1, wherein:
the first memory layer further comprises a memory cell coupled to the first word line,
the memory cell comprises a transistor and a capacitor,
the transistor comprises a channel region and an electrode over the channel region, and
the first word line is coupled to the electrode.

6. The IC device according to claim 1, wherein the logic layer comprises a P-type metal-oxide-semiconductor transistor and a N-type metal-oxide-semiconductor transistor.

7. The IC device according to claim 1, further comprising:
a third memory layer at the first side or the second side of the logic layer, the third memory layer comprising a third word line; and
a conductive structure between the first word line and the third word line,
wherein the third word line is coupled to the first word line through the conductive structure.

8. An integrated circuit (IC) device, comprising:
a logic layer comprising a sense amplifier;
a first memory layer at a first side of the logic layer, the first memory layer comprising first memory cells and a first bit line coupled to the first memory cells; and
a second memory layer at a second side of the logic layer, the second memory layer comprising second memory cells and a second bit line coupled to the second memory cells,
wherein the second side opposes the first side, and the first bit line and the second bit line are coupled to the sense amplifier.

9. The IC device according to claim 8, wherein:
the logic layer further comprises a first word line driver and a second word line driver,
the first memory layer further comprises a first word line coupled to the first word line driver, and
the second memory layer further comprises a second word line coupled to the second word line driver that is separate from the first word line driver.

10. The IC device according to claim 9, wherein the first word line is separated from the second word line by an electrical insulator.

11. The IC device according to claim 8, further comprising:
a bonding layer between the logic layer and the first memory layer,
wherein the bonding layer comprises conductive structures, an individual conductive structure is coupled to the first bit line, and a pitch of the conductive structures is approximately 100nanometers to 15 micrometers.

12. The IC device according to claim 8, wherein:
an individual first memory cell comprises a transistor and a capacitor,
the transistor comprises a source region, a drain region, and an electrode over the source region or drain region, and
the first bit line is coupled to the electrode.

13. The IC device according to claim 8, wherein the logic layer comprises a P-type metal-oxide-semiconductor transistor and a N-type metal-oxide-semiconductor transistor.

14. The IC device according to claim 8, further comprising:
a third memory layer at the first side or the second side of the logic layer, the third memory layer comprising a third bit line,
wherein the third bit line is coupled to the sense amplifier.

15. An integrated circuit (IC) device, comprising:
a logic layer comprising a first sense amplifier and a second sense amplifier;
a first memory layer at a first side of the logic layer, the first memory layer comprising first memory cells and a first bit line coupled to the first memory cells;
a second memory layer at the first side of the logic layer, the second memory layer comprising second memory cells and a second bit line coupled to the second memory cells; and
a third memory layer at a second side of the logic layer, the third memory layer comprising third memory cells and a third bit line coupled to the third memory cells,
wherein the first memory layer is between the second memory layer and the logic layer, the second side opposes the first side, the first bit line and the third bit line are coupled to the first sense amplifier, and the second bit line are coupled to the second sense amplifier that is separate from the first sense amplifier.

16. The IC device according to claim 15, further comprising:
a fourth memory layer at a second side of the logic layer, the fourth memory layer comprising fourth memory cells and a fourth bit line coupled to the fourth memory cells,
wherein the third memory layer is between the fourth memory layer and the logic layer, and the fourth bit line is coupled to the second sense amplifier.

17. The IC device according to claim 15, wherein:
the first memory layer further comprises a first word line coupled to the first memory cells,
the second memory layer further comprises a second word line coupled to the second memory cells,
the third memory layer further comprises a third word line coupled to the third memory cells,
the logic layer further comprises a first word line driver and a second word line driver that is separate from the first word line driver,
the first word line and the second word line are coupled to the first word line driver, and
the third word line is coupled to the second word line driver.

18. The IC device according to claim 17, further comprising:
a fourth memory layer at a second side of the logic layer, the fourth memory layer comprising fourth memory cells and a fourth word line coupled to the fourth memory cells,
wherein the third memory layer is between the fourth memory layer and the logic layer, and the fourth word line is coupled to the second word line driver.

19. The IC device according to claim 15, further comprising:
a bonding layer between the logic layer and the first memory layer,
wherein the bonding layer comprises conductive structures, an individual conductive structure is coupled to the first bit line, and a pitch of the conductive structures is approximately 100 nanometers to 15 micrometers.

20. The IC device according to claim 15, wherein the logic layer comprises a P-type metal-oxide-semiconductor transistor and a N-type metal-oxide-semiconductor transistor.
